(19) United States
(12) Patent Application Publication
(10) Pub. No.: US 2026/0362785 A1
(43) Pub. Date: Nov. 12, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Chia-Hao CHANG, Hsinchu City (TW); I-Han HUANG, New Taipei City (TW); Kuo-Cheng CHIANG, Hsinchu County (TW)

(73) Assignee: TAIWAN SEMICONDUCTOR MANUFACTURING COMPANY, LTD., Hsinchu (TW)

(21) Appl. No.: 19/203,411

(22) Filed: May 9, 2025

(51) Int. Cl. H10D 84/01; H10D 84/85

(52) U.S. Cl. CPC H10D 84/017; H10D 84/0167; H10D 84/0186; H10D 84/0188; H10D 84/851

(57) ABSTRACT

A method includes forming first and second channel regions over a substrate; forming an isolation feature disposed over the substrate and between the first and second channel regions; forming a gate structure over the first and second channel regions; forming a first source/drain feature interfacing a sidewall of the first channel region; forming an etch stop layer continuously extending from over the first source/drain feature to over the second source/drain feature; forming an interlayer dielectric (ILD) layer over the etch stop layer; patterning the first channel region to form a first sub-channel region and a second sub-channel region, wherein the gate structure overlying the first channel region is concurrently patterned to form a first sub-gate structure over the first sub-channel region and a second sub-gate structure over the second sub-channel region.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nano-FETs (e.g., nanowire FETs, nanosheet FETs (Nano-FETs), or the like) in a three-dimensional view, in accordance with some embodiments.

FIGS. 2-19 illustrate schematic views of intermediate stages in the formation of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Previous technologies encountered challenges in transistor scaling, particularly when reducing the active region (OD) space. Issues included epitaxial bridge formation, causing unintended connectivity, and the absence of multi-patterning gate (MPG) and cut-metal gate (CMG) windows, restricting active region patterning and metal gate definition. Additionally, lateral epitaxial growth variations led to inconsistencies. Therefore, the present disclosure introduces a method for cell height scaling in transistors, enabling active region space reduction while overcoming fabrication challenges. The method introduces a wall-fill process, preventing epitaxial bridging, gate misalignment, and work function metal (WFM) damage, which in turn optimizes MPG and cut-metal gate CMG windows, enhances lateral epitaxial growth control, and improves isolation through dielectric wall, and therefore ensuring higher device density and improving process scalability and transistor performance.

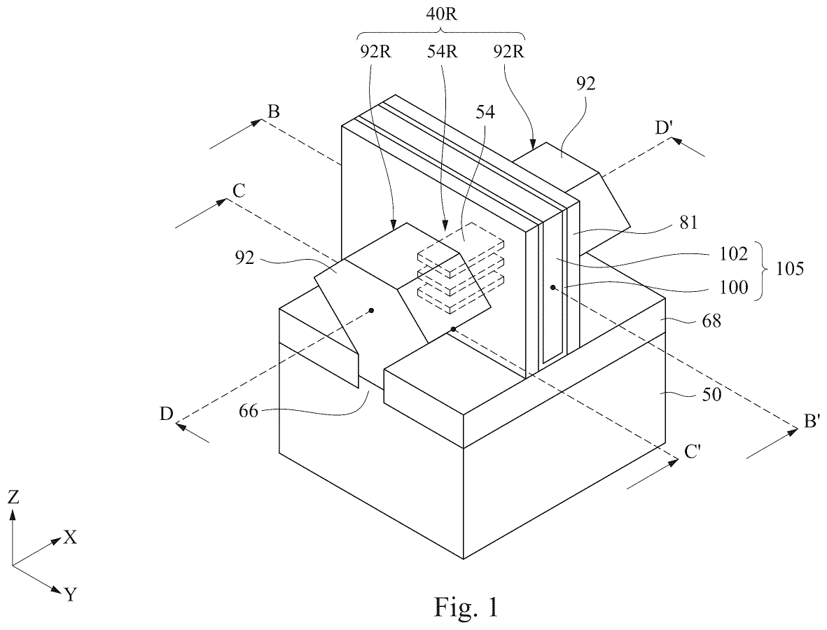

Reference is made to FIG. 1. FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over a fin 66 on a substrate 50 (e.g., a semiconductor substrate), wherein the nanostructures 54 act as channel regions for the nano-FCTs. The nanostructure 54 may include p-type nanostructures, n-type nanostructures, or a combination thereof. Shallow trench isolation (STI) regions 68 (also referred to as STI structures) are disposed between adjacent fin 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fin 66 are illustrated as being single, continuous materials with the substrate 50, the bottom portion of the fin 66 and/or the substrate 50 may comprise a single material or a plurality of materials. In this context, the fin 66 can refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain structures 92 are disposed on the fins 66 on opposing sides of the gate dielectric layers 100 and the gate electrodes 102. Source/drain region(s) 92 may refer to a source or a drain, individually or collectively dependent upon the context. In some embodiments, the nanostructures 54 can be formed on a channel region 54R, the epitaxial source/drain structures 92 can be formed on source/drain regions 92R, and the channel region 54R and the source/drain regions 92R can be collectively referred to as an active region 40R.

FIG. 1 further illustrates reference cross-sections that are used in later figures. Cross-section B-B′ is along a longitudinal axis of a gate electrode 102 and in a direction, for example, perpendicular to the direction of current flow between the epitaxial source/drain structures 92 of a nano-FET. Cross-section C-C′ is parallel to cross-section B-B′ and extends through epitaxial source/drain regions of the nano-FETs. Cross-section D-D′ is perpendicular to cross-section C-C′ and is parallel to a longitudinal axis of a fin 66 of the nano-FET and in a direction of, for example, a current flow between the epitaxial source/drain structures 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

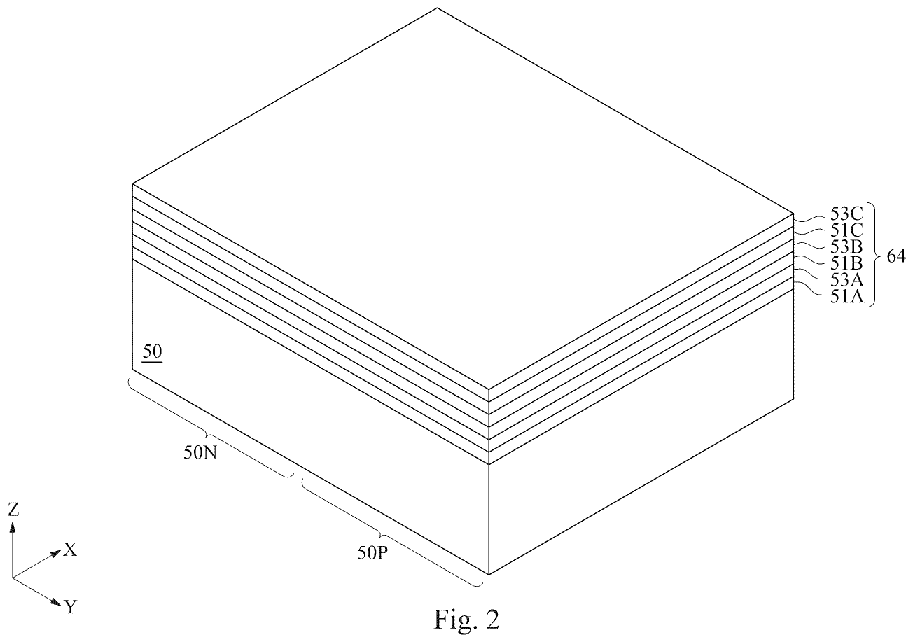

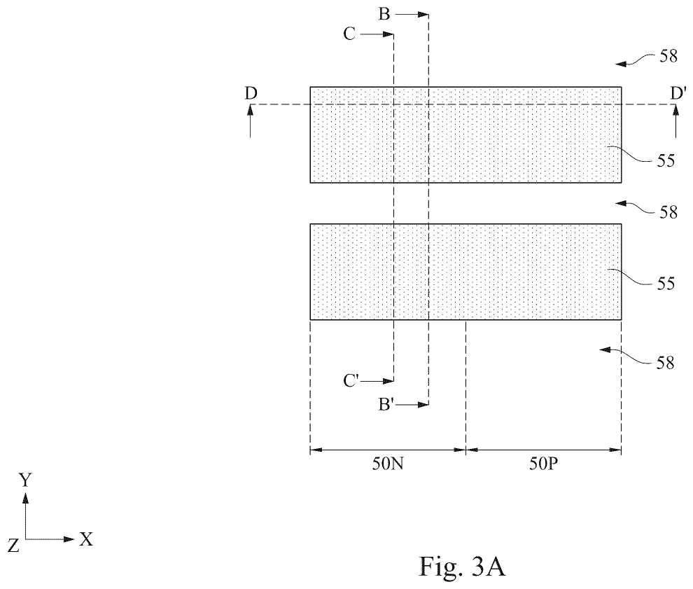

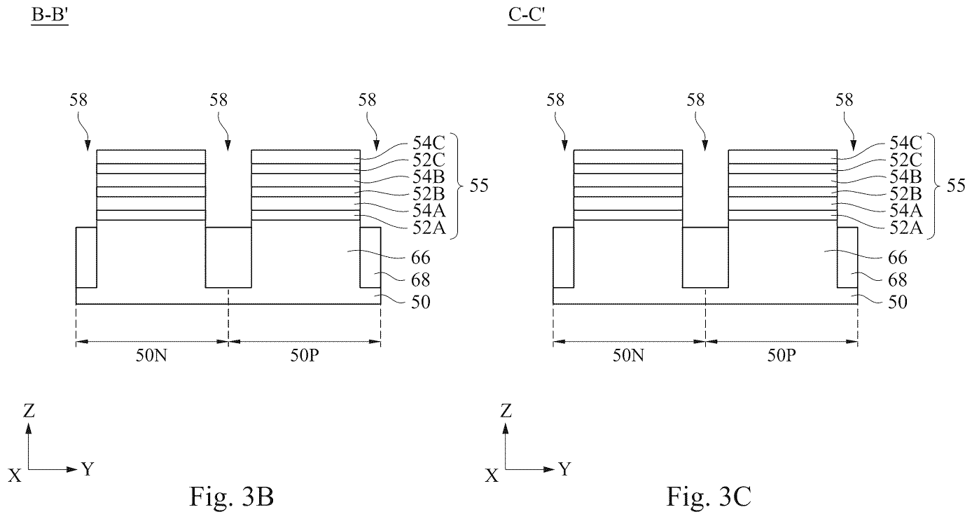

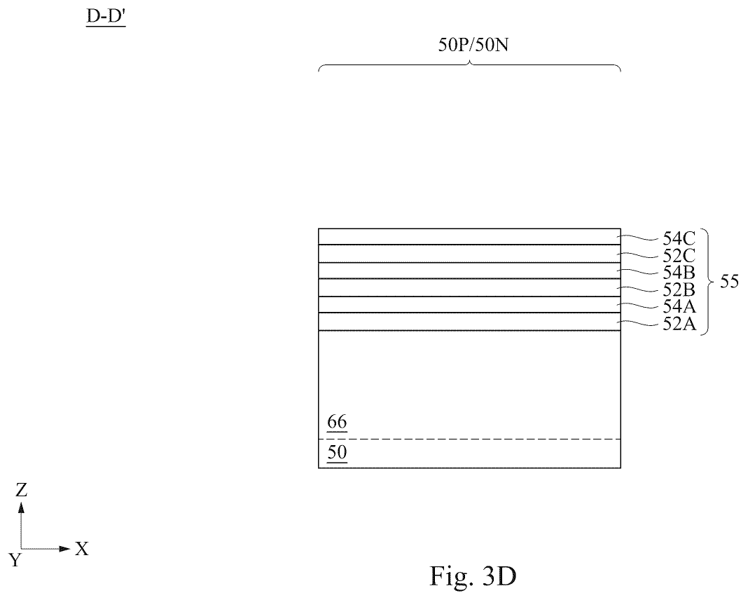

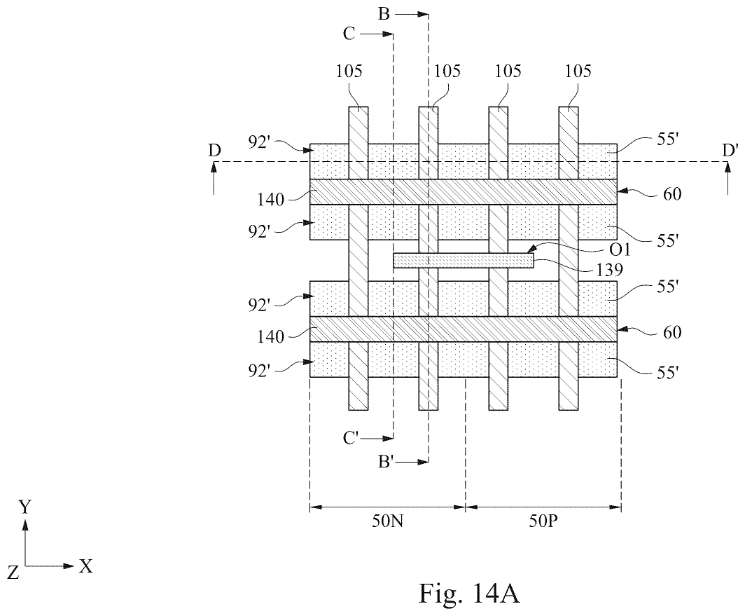

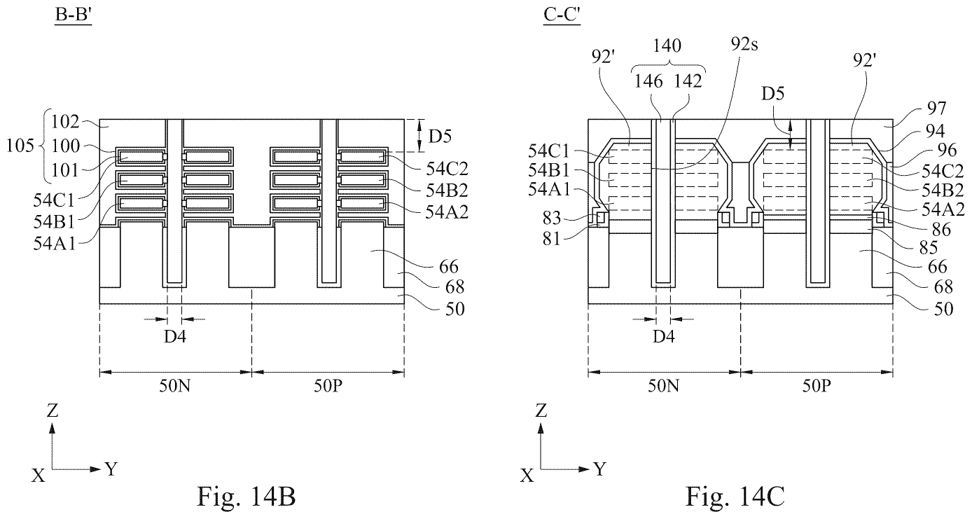

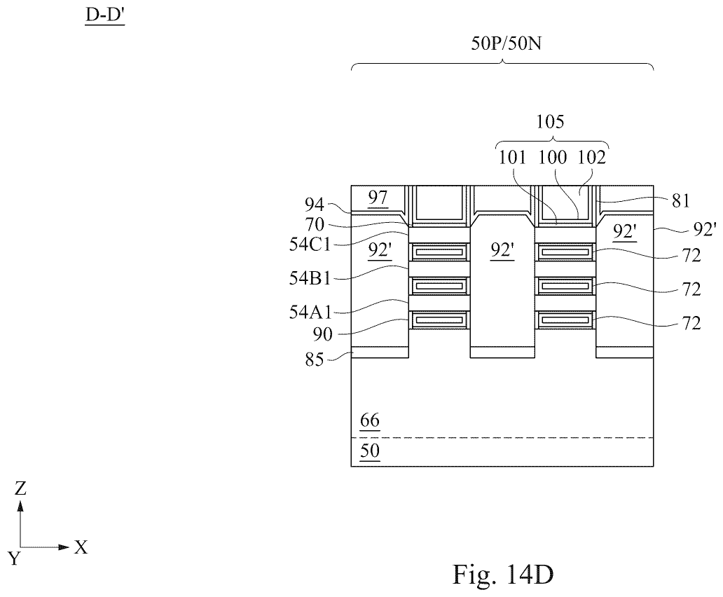

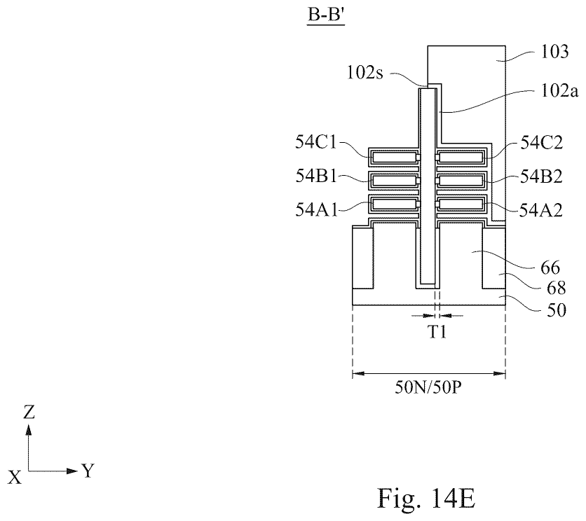

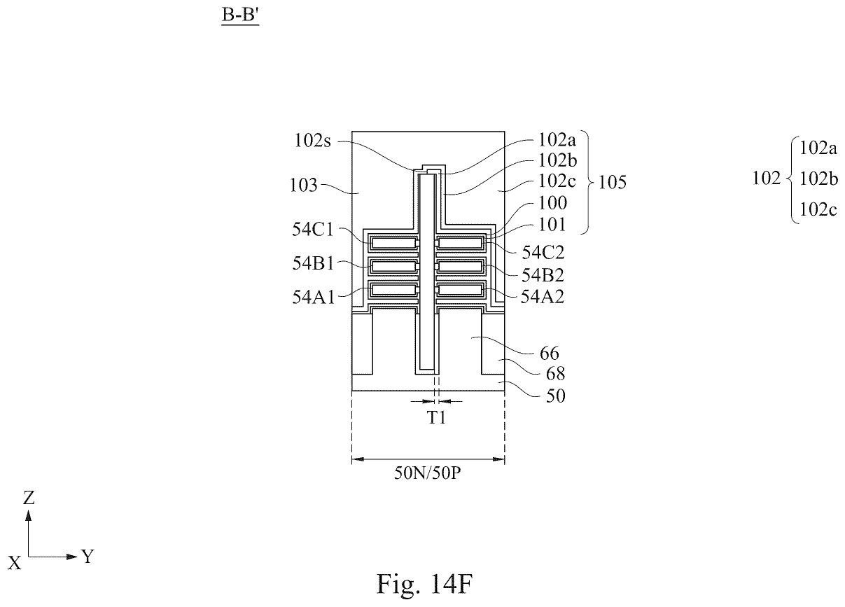

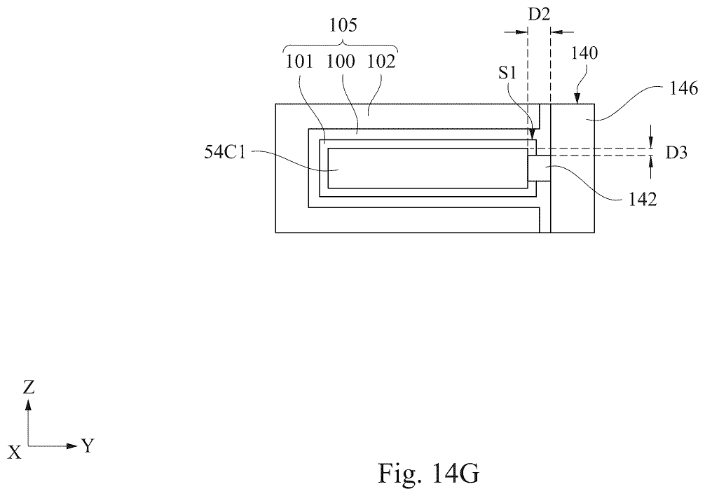

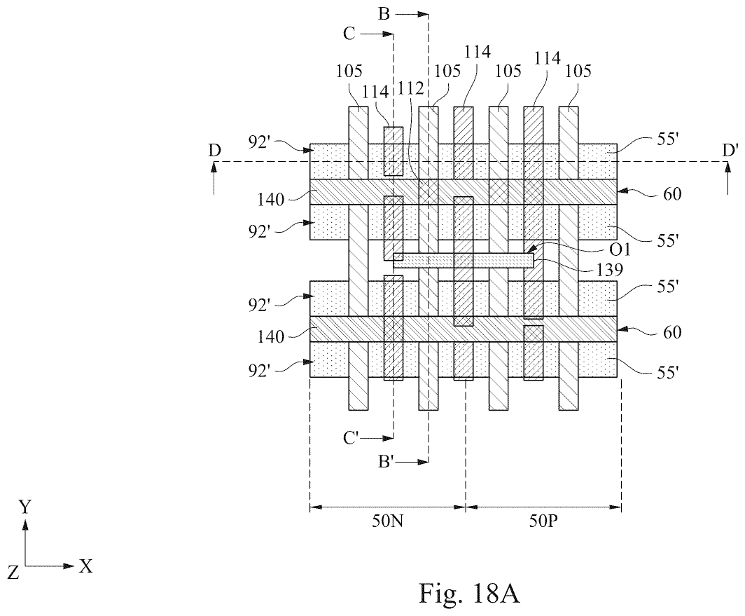

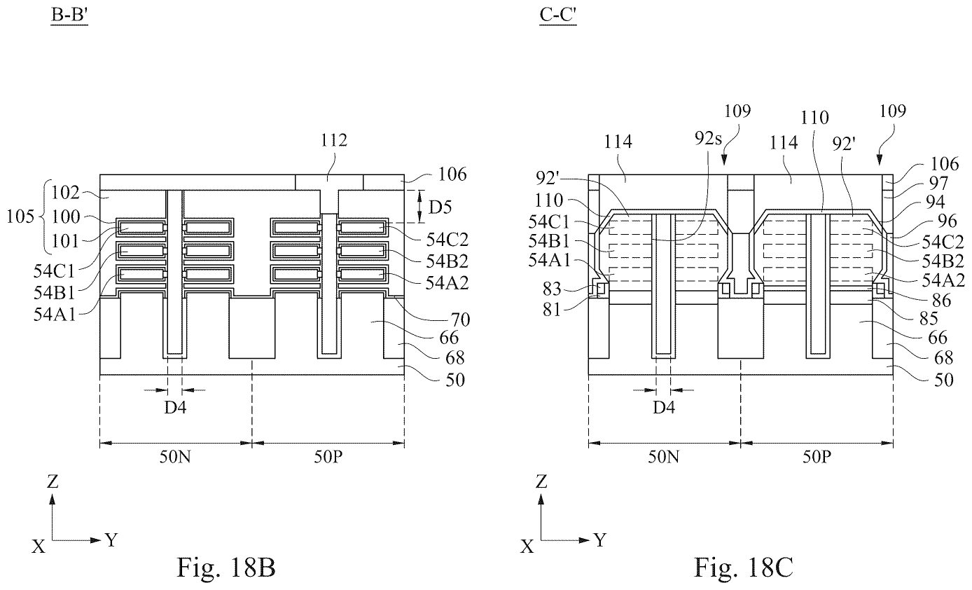

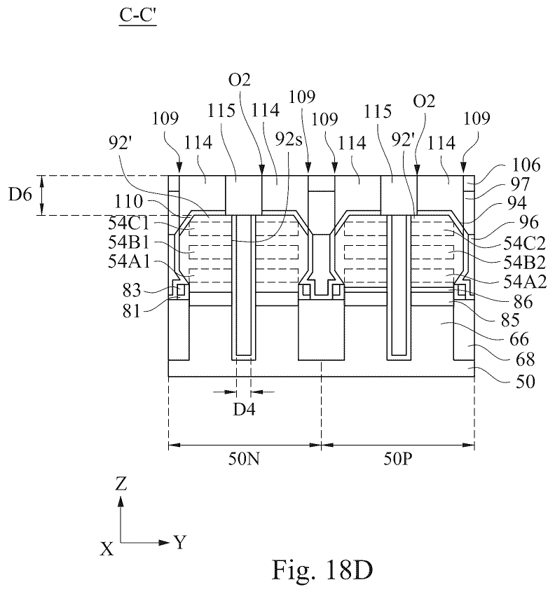

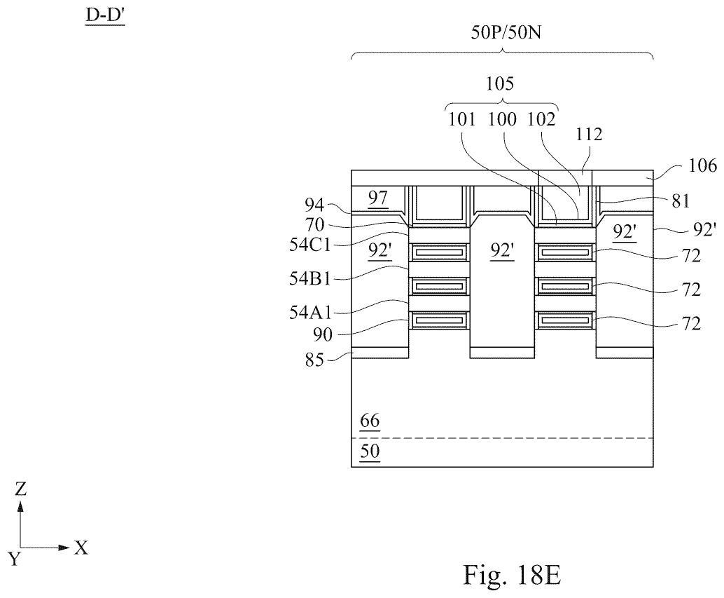

Reference is made to FIGS. 2-19. FIGS. 2-19 illustrate schematic views of intermediate stages in the formation of a semiconductor structure in accordance with some embodiments of the present disclosure. Specifically, FIG. 2 illustrates a schematic perspective view of the semiconductor structure in accordance with some embodiments of the present disclosure. FIGS. 3A, 4A, 10A, 11A, 12A, 13A, 14A, 15A, 16A, 17A, and 18A illustrate schematic top views of the semiconductor structure in accordance with some embodiments of the present disclosure. FIGS. 3B, 4B, 5A, 6A, 7A, 8A, 9A, 10B, 11B, 12B, 13B, 14B, 15B, 16B, 17B, and 18B illustrate schematic cross-sectional views obtained from reference cross-sections B-B′ in FIGS. 3A, 4A, 10A, 11A, 12A, 13A, 14A, 15A, 16A, 17A, and 18A, respectively. FIGS. 3C, 4C, 5B, 6B, 7B, 8B, 9B, 10C, 11C, 12C, 13C, 14C, 15C, 16C, 17C, and 18C illustrate schematic cross-sectional views obtained from reference cross-sections C-C′ in FIGS. 3A, 4A, 10A, 11A, 12A, 13A, 14A, 15A, 16A, 17A, and 18A, respectively. FIGS. 3D, 4D, 5C, 6C, 7C, 8C, 9C, 10D, 11D, 12D, 13D, 14D, 15D, 16D, 17D, 18E, and 19 illustrate schematic cross-sectional views obtained from reference cross-sections D-D′ in FIGS. 3A, 9A, 10A, 11A, 12A, 13A, 14A, 15A, 16A, 17A, and 18A, respectively. FIGS. 14E and 14F illustrate schematic cross-sectional views of a semiconductor structure corresponding to FIG. 14B in accordance with some embodiments of the present disclosure. FIG. 14G illustrates a schematic enlarged view of a region in FIG. 14B in accordance with some embodiments of the present disclosure. FIG. 18D illustrates a schematic cross-sectional view of a semiconductor structure corresponding to FIG. 18C in accordance with some embodiments of the present disclosure. It is understood that additional operations can be provided before, during, and after the processes shown by FIGS. 2-19, and some of the operations described below can be replaced or eliminated, for additional embodiments of the method. The order of the operations/processes may be interchangeable.

Reference is made to FIG. 2. A substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

Reference is made to FIGS. 3A-3D. Fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIGS. 3A-3D illustrate the fins 66 having substantially equal widths for illustrative purposes. In some embodiments, widths of the fins 66 in the n-type region 50N may be greater or thinner than the fins 66 in the p-type region 50P. Further, while FIGS. 3A-3D illustrate each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIGS. 3A-3D, shallow trench isolation (STI) regions 68 are formed adjacent the fins 66. The STI regions 68 may be formed by depositing an insulation material over the substrate 50, the fins 66, and the nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIGS. 3A-3D, appropriate wells (not separately illustrated) may be formed in the fins 66 and the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 1013 atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

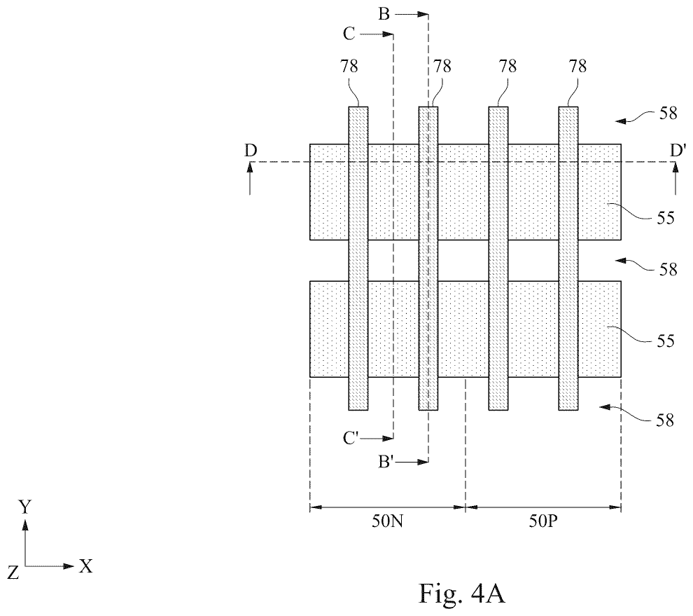

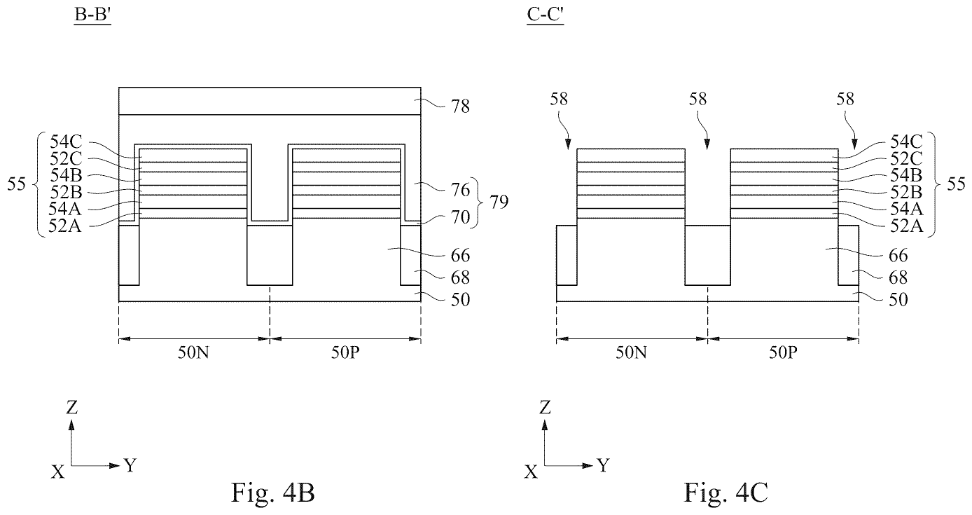

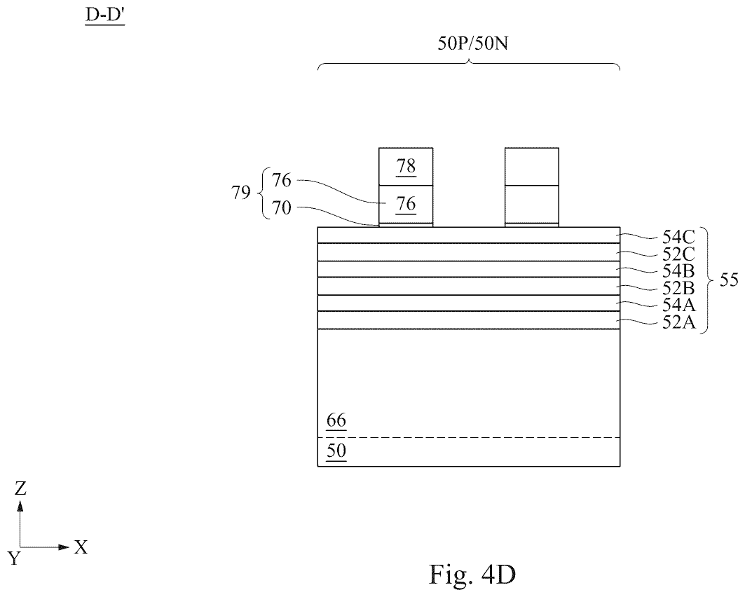

Reference is made to FIGS. 4A-4D. Dummy gate structures 79 are formed over and along sidewalls of the nanostructures 55 and the fin 66. To form the dummy gate structures 79, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. The dummy dielectric layer may extend into the nanostructure cuts 60. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like. In some embodiments, the dummy gate structure 79 can be interchangeable referred to as a gate structure, a gate layer, a gate pattern, a gate line, or a gate.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise (or longitudinal) direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68. In some embodiments, the dummy gate structures 79 can interface the top surface of the STI region 68.

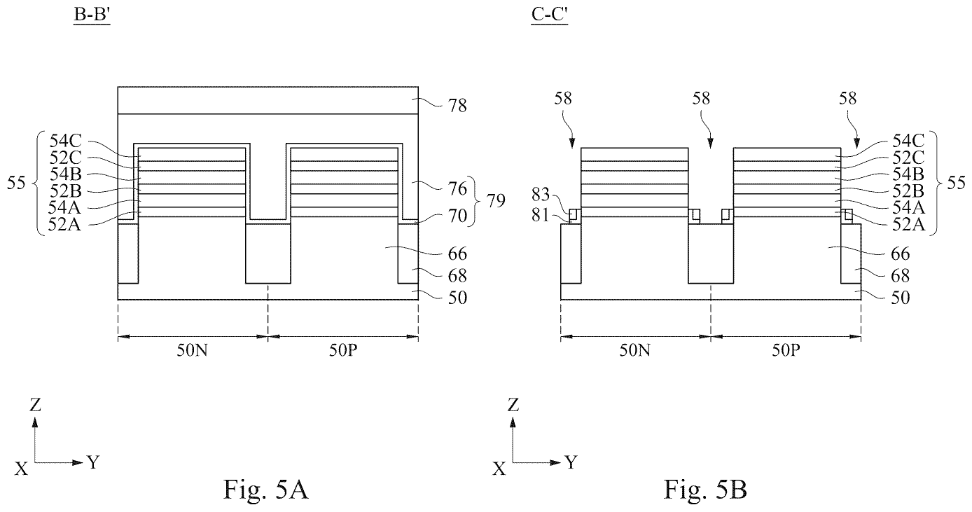

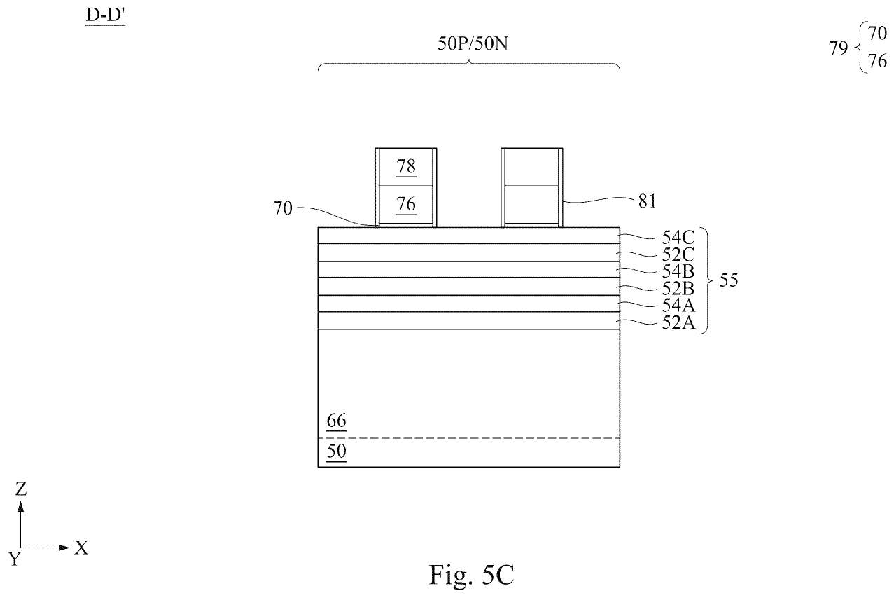

Reference is made to FIGS. 5A-5C. A first spacer layer and a second spacer layer are formed over the structures illustrated in FIGS. 4A-4D. The first spacer layer and the second spacer layer will be subsequently patterned to act as spacers for forming self-aligned source/drain regions. In FIGS. 5A-5C, the first spacer layer is formed on top surfaces of the STI regions 68; top surfaces and sidewalls of the fins 66, the nanostructures 55, and the masks 78; and sidewalls of the dummy gates 76 and the dummy gate dielectric 70. The second spacer layer is deposited over the first spacer layer. The first spacer layer may be formed of silicon oxide, silicon nitride, silicon oxynitride, or the like, using techniques such as thermal oxidation or deposited by CVD, ALD, or the like. The second spacer layer may be formed of a material having a different etch rate than the material of the first spacer layer, such as silicon oxide, silicon nitride, silicon oxynitride, or the like, and may be deposited by CVD, ALD, or the like.

After the first spacer layer is formed and prior to forming the second spacer layer, implants for lightly doped source/drain (LDD) regions (not separately illustrated) may be performed. In embodiments with different device types, similar to the implants discussed above in FIGS. 3A-3D, a mask, such as a photoresist, may be formed over the n-type region 50N, while exposing the p-type region 50P, and appropriate type (e.g., p-type) impurities may be implanted into the exposed fins 66 and the nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and the nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 1×10¹⁵ atoms/cm³ to 1×10¹⁹ atoms/cm³. An anneal may be used to repair implant damage and to activate the implanted impurities.

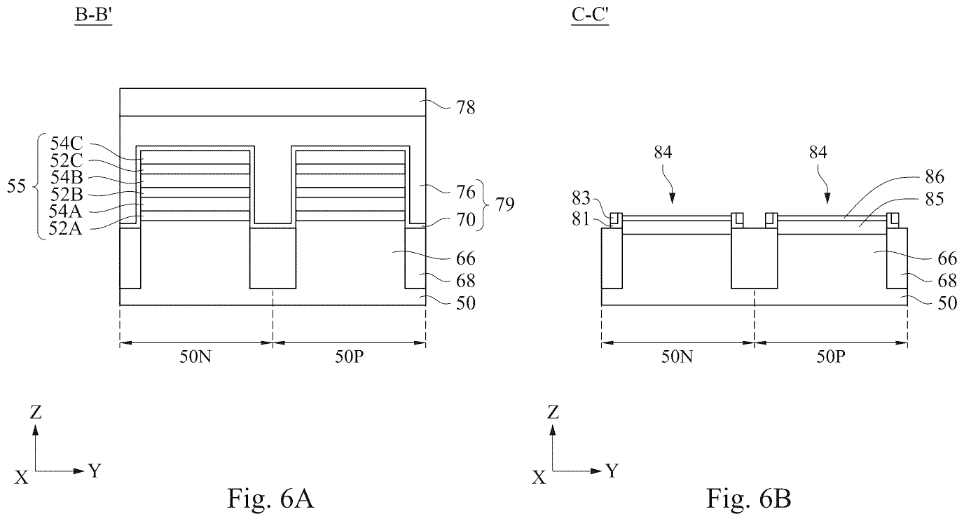

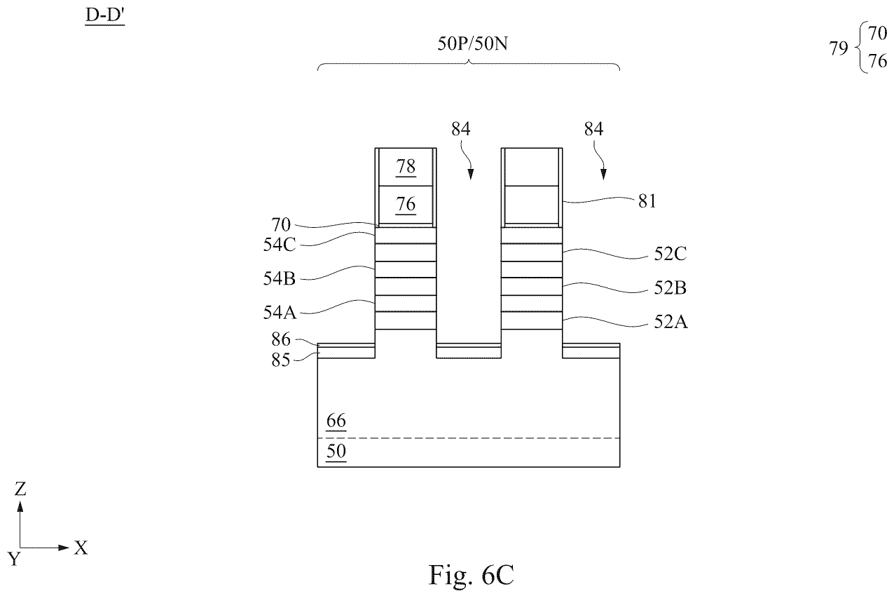

In FIGS. 5A-5C, the first spacer layer and the second spacer layer are etched to form first spacers 81 and second spacers 83. As will be discussed in greater detail below, the first spacers 81 and the second spacers 83 act to self-align subsequently formed source drain regions, as well as to protect sidewalls of the fins 66, and/or the nanostructure 55 during subsequent processing. The first spacer layer and the second spacer layer may be etched using a suitable etching process, such as an isotropic etching process (e.g., a wet etching process), an anisotropic etching process (e.g., a dry etching process), or the like. In some embodiments, the material of the second spacer layer has a different etch rate than the material of the first spacer layer, such that the first spacer layer may act as an etch stop layer when patterning the second spacer layer and such that the second spacer layer may act as a mask when patterning the first spacer layer. For example, the second spacer layer may be etched using an anisotropic etch process wherein the first spacer layer acts as an etch stop layer, wherein remaining portions of the second spacer layer form second spacers 83 as illustrated in FIG. 6B. Thereafter, the second spacers 83 acts as a mask while etching exposed portions of the first spacer layer, thereby forming first spacers 81 as illustrated in FIG. 6B. In FIG. 6B, first spacers 81 and second spacers 83 are both formed in the nanostructure cut 60, but in some embodiments, the spacers are not formed in the nanostructure cut 60.

As illustrated in FIG. 6B, the first spacers 81 and the second spacers 83 are disposed on sidewalls of the fins 66 and/or nanostructures 55. As illustrated in FIG. 6C, in some embodiments, the second spacer layer may be removed from over the first spacer layer adjacent the masks 78, the dummy gates 76, and the dummy gate dielectrics 70, and the first spacers 81 are disposed on sidewalls of the masks 78, the dummy gates 76, and the dummy gate dielectrics 70. In other embodiments, a portion of the second spacer layer may remain over the first spacer layer adjacent the masks 78, the dummy gates 76, and the dummy gate dielectrics 70.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer), additional spacers may be formed and removed, and/or the like. Furthermore, the n-type and p-type devices may be formed using different structures and steps.

Reference is made to FIGS. 6A-6C. First recesses 84 are formed in the fins 66, the nanostructures 55 and the substrate 50, in accordance with some embodiments. Epitaxial source/drain regions will be subsequently formed in the first recesses 84. The first recesses 84 may extend through the first nanostructures 52 and the second nanostructures 54, and into the substrate 50. As illustrated in FIG. 6B, the fins 66 may be etched such that bottom surfaces of the first recesses 84 are disposed above or below the top surfaces of the STI regions 68. In other embodiments, top surfaces of the STI regions 68 may be level with bottom surfaces of the first recesses 84. The first recesses 84 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 84. A single etch process or multiple etch processes may be used to etch each layer of the nanostructures 55 and/or the fins 66. Timed etch processes may be used to stop the etching of the first recesses 84 after the first recesses 84 reach a desired depth.

Subsequently, a semiconductive layer 85 can be formed over the fin 66, serving as a structural compensation for excessive recessing of the fin 66 caused by the formation of recess 84. Depending on this embodiment, the top surface of semiconductive layer 85 may be positioned higher than, lower than, or level with the top surface of the STI regions 68. In some embodiments, the top surface of semiconductive layer 85 can be lower than the top surfaces of both the gate spacer 81 and the fin spacer 83. The material composition of semiconductive layer 85 can either be the same as that of fin 66 or a different material. Possible materials for the semiconductive layer 85 can include silicon, germanium, and various compound semiconductors such as silicon carbide (SiC), gallium arsenide (GaAs), gallium phosphide (GaP), indium phosphide (InP), indium arsenide (InAs), and indium antimonide (InSb). Additionally, alloy semiconductors like silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP) may also be used.

The formation of semiconductive layer 85 can be achieved through epitaxial growth using techniques such as chemical vapor deposition (CVD), molecular beam epitaxy (MBE), or atomic layer deposition (ALD), ensuring control over layer thickness, doping levels, and material composition. Alternatively, selective deposition processes can be employed to deposit material only in targeted areas (i.e., fin 66). In situ doping during deposition or post-deposition ion implantation followed by annealing can be used to tailor the electrical properties of the semiconductive layer 85. The formation of semiconductive layer 85 can provide structural restoration by compensating for excessive recessing of the fin 66, ensuring uniformity and robustness in device fabrication, optimizing electrical performance by improving carrier mobility and reducing resistance through material selection, enhancing process control by allowing fine-tuning of the interface properties between fin 66 and the source/drain regions.

Subsequently, a dielectric layer 86 can be formed over the semiconductive layer 85, serving as an insulating layer to electrically isolate the underlying semiconductor structures while providing additional structural stability. In some embodiments, the top surface of dielectric layer 86 can be positioned lower than the top surfaces of the gate spacer 81 and the the fin spacer 83, ensuring compatibility with the overall device architecture and preventing interference with subsequent processing steps. The dielectric layer 86 may be made of an insulating material such as silicon oxide (SiO₂), silicon oxynitride (SiON), aluminum oxide (Al₂O₃), or other dielectric materials that can be selectively etched from the second nanostructures 54. The formation of dielectric layer 86 can be achieved through various deposition techniques, including chemical vapor deposition (CVD), plasma-enhanced CVD (PECVD), atomic layer deposition (ALD), and spin-on deposition (SOD). CVD and PECVD are used for uniform layer deposition across complex structures. After deposition, the dielectric layer 86 may undergo additional selective etching process to achieve the required thickness and surface smoothness and refine its coverage and alignment with other device layers. The formation of dielectric layer 86 can improve electrical insulation between semiconductor structures, reduced parasitic capacitance, and enhanced device reliability by preventing unintended electrical leakage. Furthermore, dielectric layer 86 acts as a buffer layer that protects underlying semiconductor materials during subsequent processing, minimizing the risk of contamination and damage while maintaining the overall integrity of the device structure.

In some embodiments, the semiconductive layer 85 and the dielectric layer 86 can be formed after the formation of the sacrificial material 72. Following the removal of the first nanostructures and the deposition of the sacrificial material 72 into the resulting voids or recesses, the process may continue by forming the semiconductive layer 85 over the exposed surfaces of the fin 66.

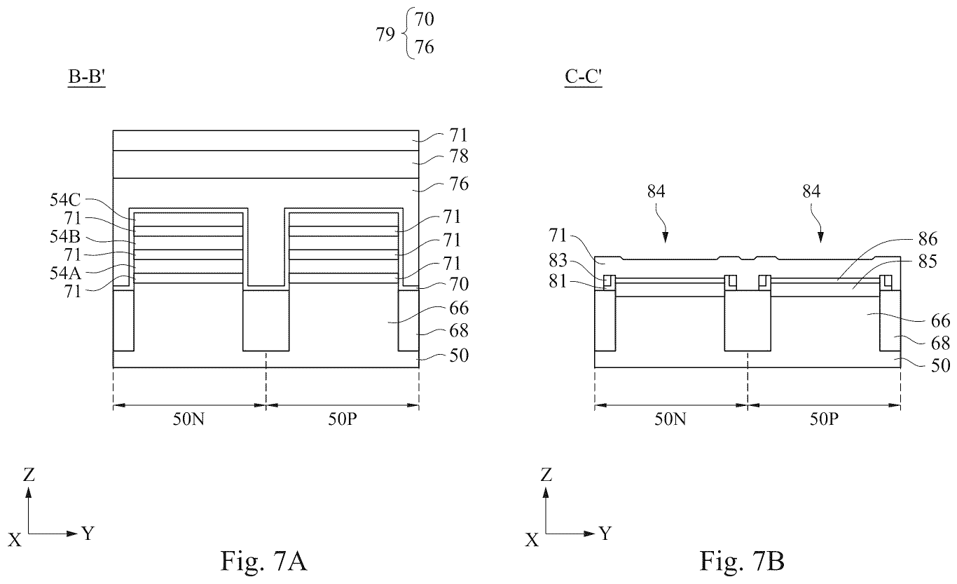

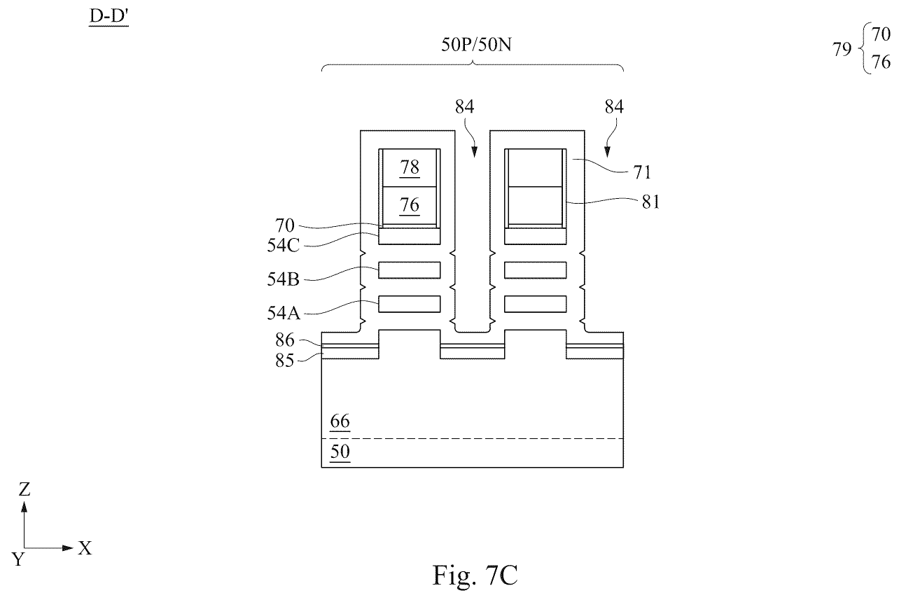

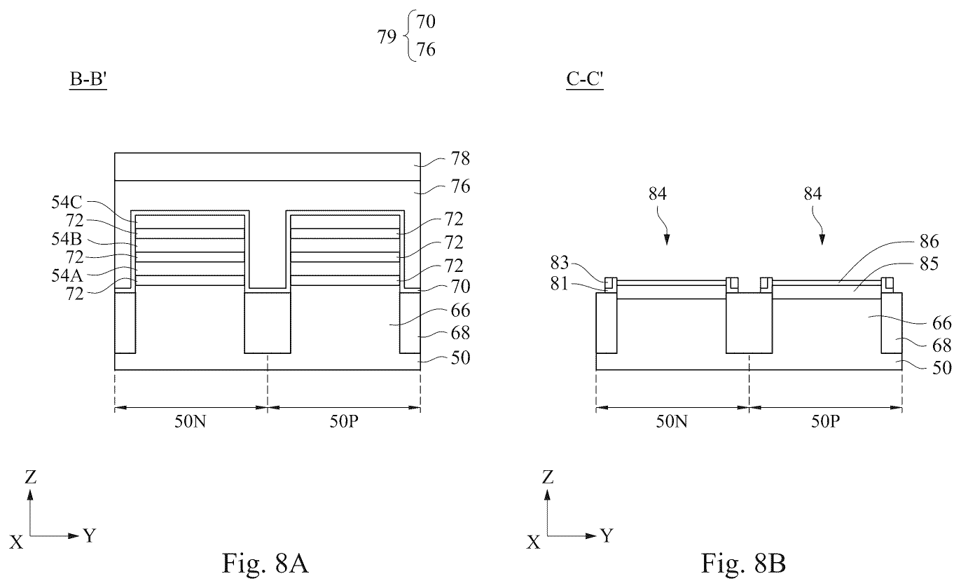

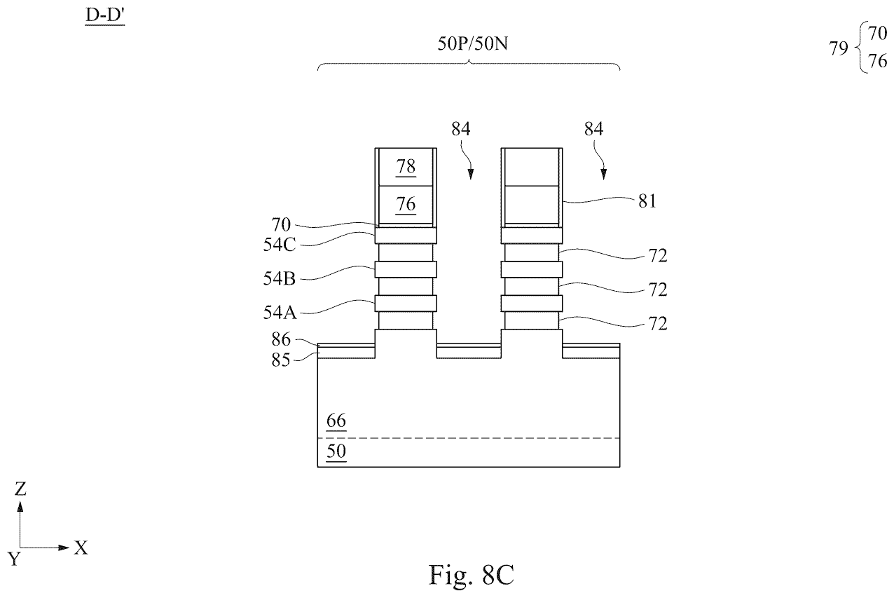

Reference is made to FIGS. 7A-8C. The first nanostructures 52 are replaced with a sacrificial material 72 (also referred to as disposable oxide interposers (DOI) 72) as shown in FIGS. 8A-8C. Replacing the first nanostructures 52 may include etching away the first nanostructures 52 using a suitable etch process, such as an isotropic etch process, that is performed through the first recesses 84 as illustrated by FIGS. 7A-7C. The etch process may be selective to the material of the first nanostructures 52 and remove the first nanostructures 52 without significantly removing the second nanostructures 54 or the fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the first recesses 84 and spaces where the first nanostructures 52 were removed. The sacrificial material layer 71 may be deposited by a conformal deposition process, such as CVD, ALD, or the like. The sacrificial material layer 71 may comprise an insulating material such as silicon oxide (e.g., SiO₂), silicon oxynitride, aluminum oxide, or the like that can be selectively etched from the second nanostructures 54.

In FIGS. 8A-8C, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 are recessed past sidewalls of the nanostructures 54. Although most of the figures in this disclosure illustrate the structures with planar surfaces and square corners, the scope of the disclosure is not limited thereto, as this disclosure also contemplates the structures having non-planar surfaces and rounded corner and profiles.

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material prior to the high-temperature processes (e.g., source/drain annealing), manufacturing defects can be reduced, and device performance can be improved (e.g., increased current drive, reduced capacitance, and improved short channel effect).

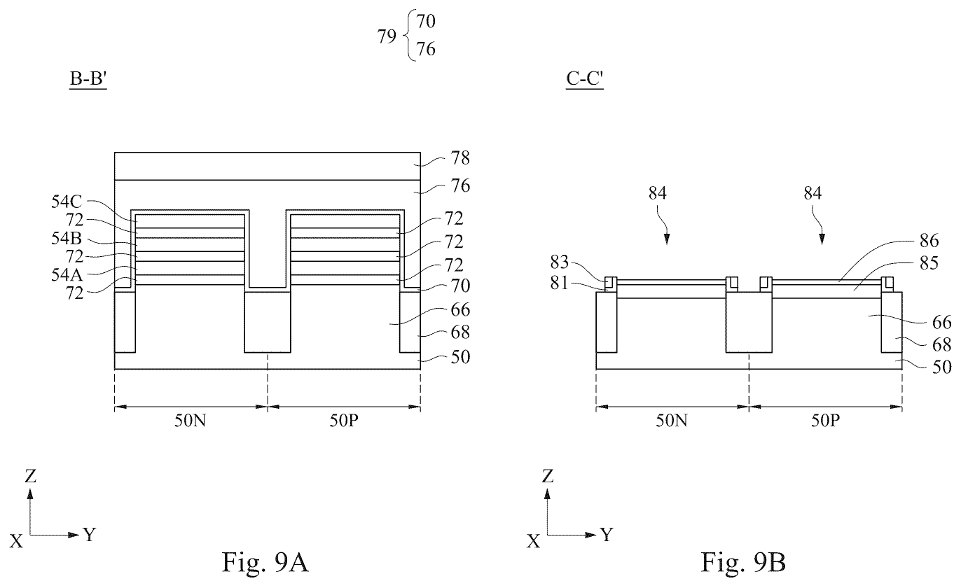

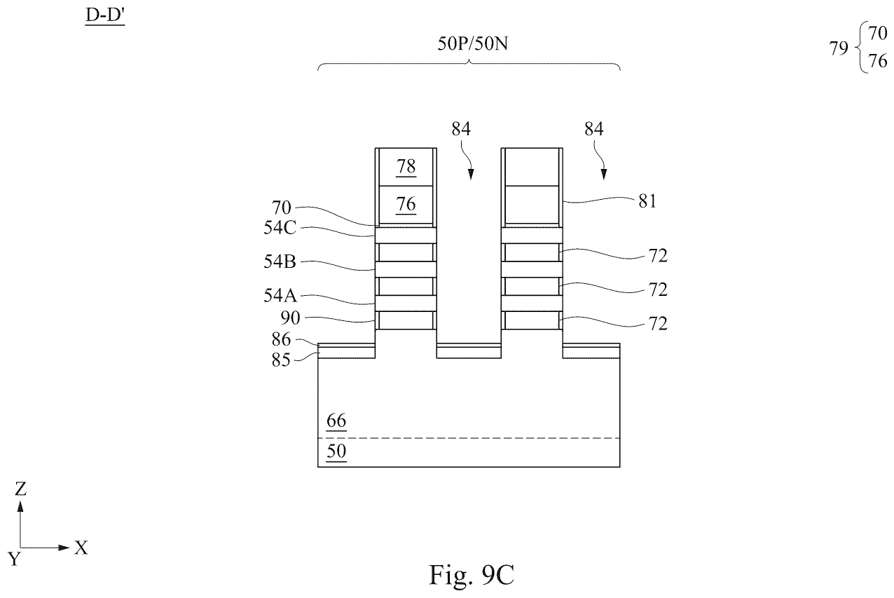

Reference is made to FIGS. 9A-9C. Inner spacers 90 are formed in the first recesses 84 on the sidewalls of the sacrificial material 72. The inner spacers 90 act as isolation features between subsequently formed source/drain regions and a gate structure. As will be discussed in greater detail below, source/drain regions will be formed in the first recesses 84, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 8A-8C. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

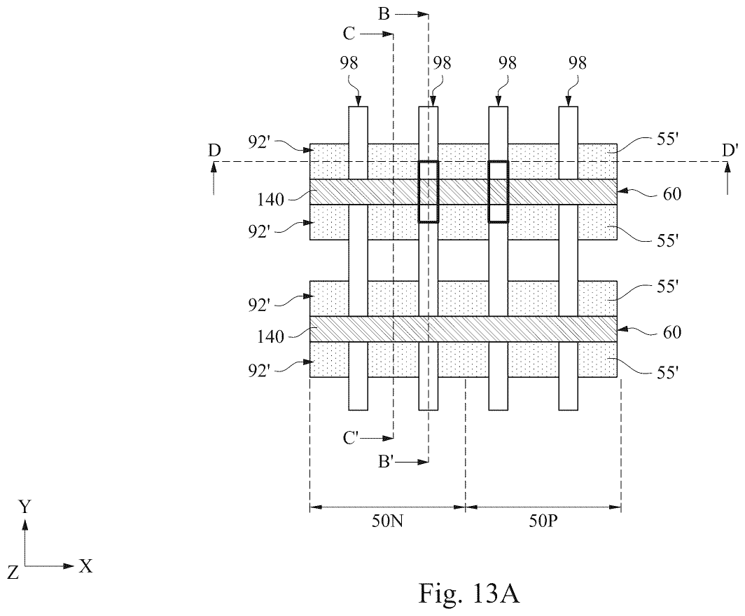

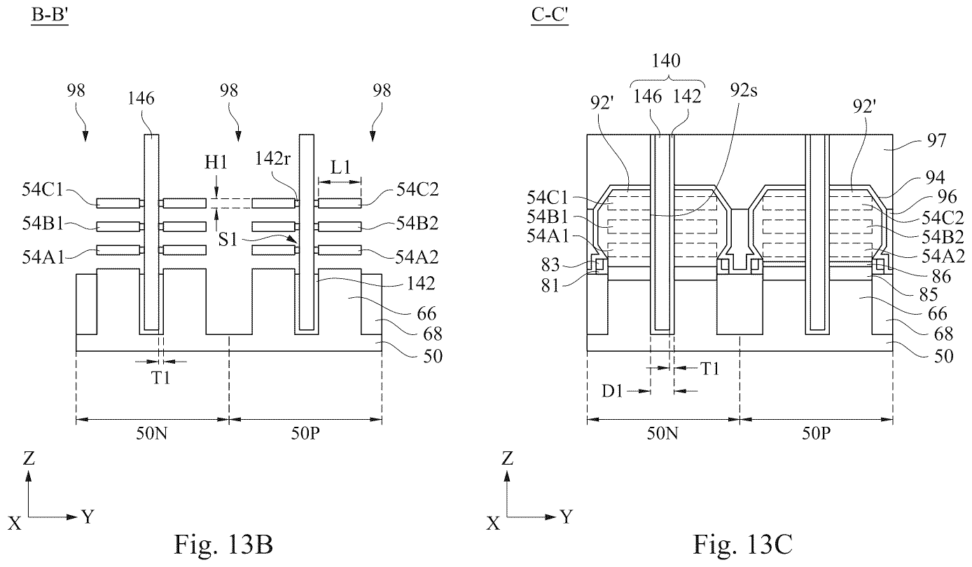

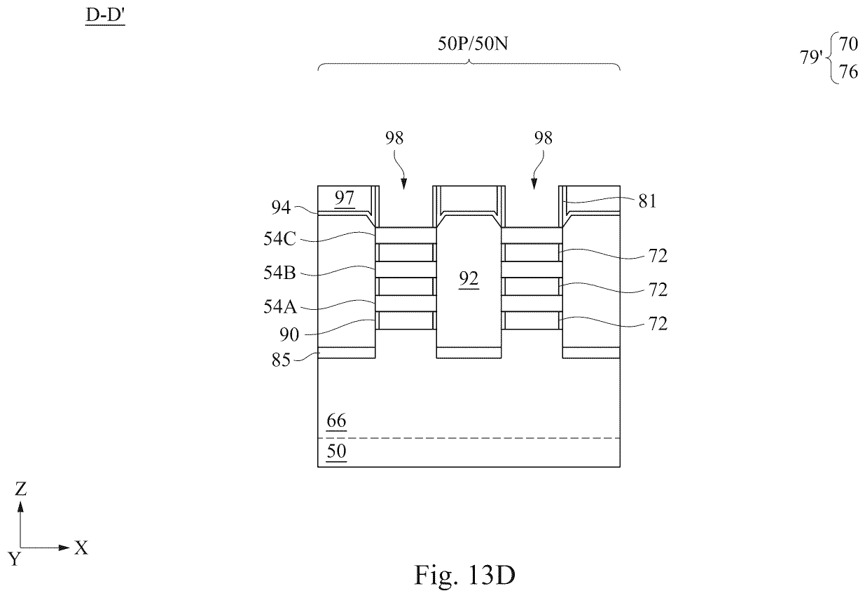

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54. Moreover, although the outer sidewalls of the inner spacers 90 are illustrated as being straight in FIG. 13C, the outer sidewalls of the inner spacers 90 may be concave or convex.

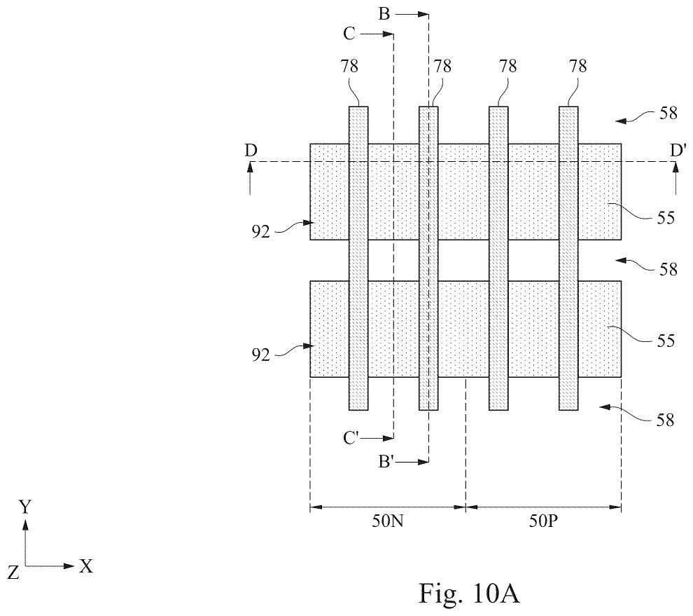

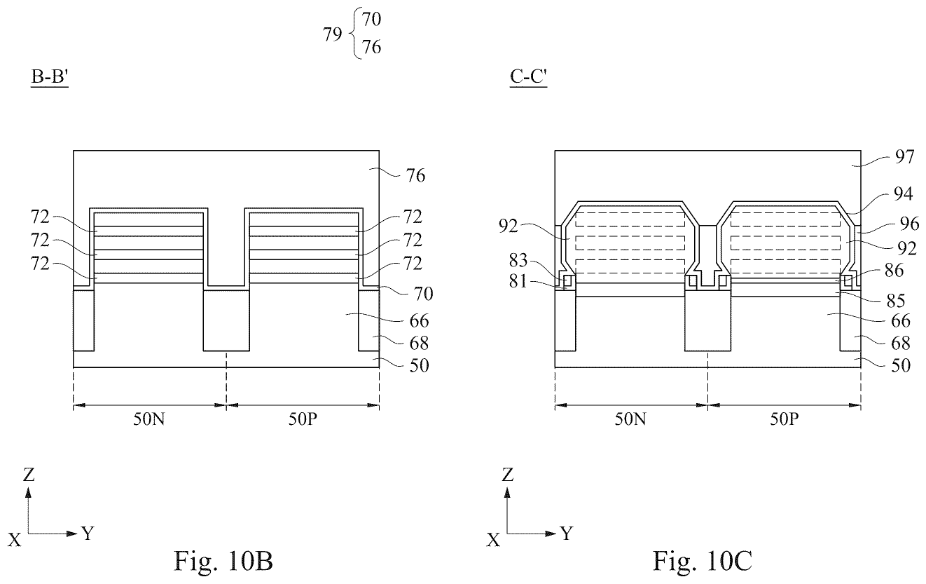

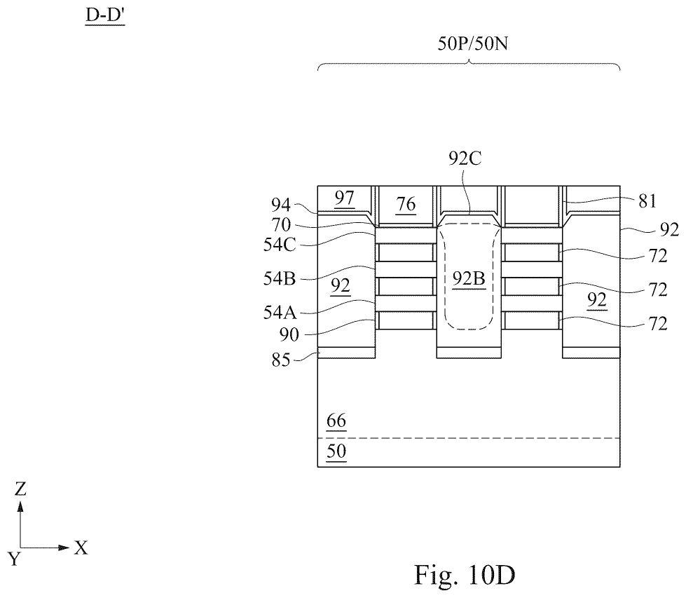

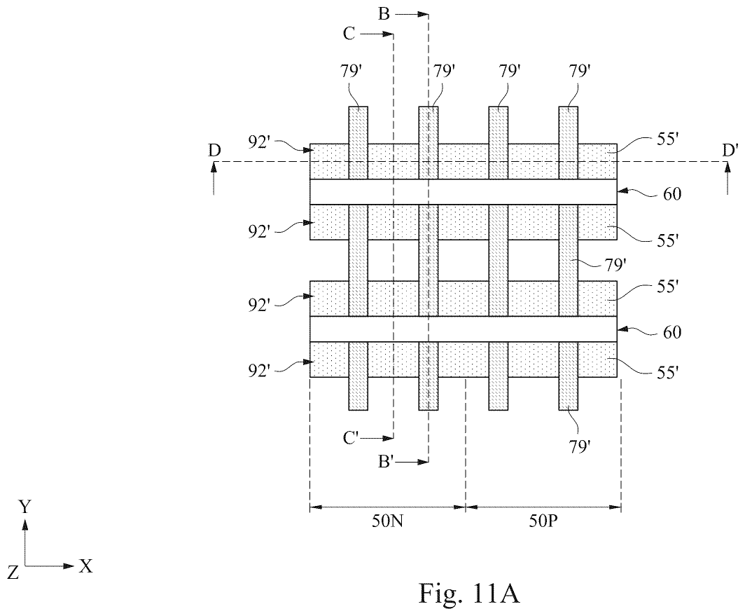

Reference is made to FIGS. 10A-10D. Epitaxial source/drain structures 92 are formed in the first recesses 84. In some embodiments, the source/drain structures 92 may exert stress on the second nanostructures 54 in the n-type region 50N and/or on the first nanostructures 52 in the p-type region 50P, thereby improving performance. As illustrated in FIG. 10D, the epitaxial source/drain structures 92 are formed in the first recesses 84 such that each dummy gate 76 is disposed between respective neighboring pairs of the epitaxial source/drain structures 92. In some embodiments, the gate spacers 81 are used to separate the epitaxial source/drain structures 92 from the dummy gates 76 and the inner spacers 90 are used to separate the epitaxial source/drain structures 92 from the sacrificial material 72 by an appropriate lateral distance so that the epitaxial source/drain structures 92 do not short out with subsequently formed gates of the resulting nano-FETs.

In some embodiment, before forming the epitaxial source/drain structures 92, the dielectric layer 86 can be selectively removed to optimize epitaxial growth conditions. Depending on this embodiment, the dielectric layer 86 can be selectively removed only from the n-type region 50N, only from the p-type region 50P, or from both regions simultaneously. In some embodiment, selective removal of dielectric layer 86 can optimize epitaxial growth conditions in nMOS and pMOS transistors, ensuring proper dopant activation, strain engineering, and source/drain resistance tuning. FIG. 10C shows an embodiment where the dielectric layer 86 is selectively removed from the n-type region 50N, while remaining in the p-type region 50P.

The removal of dielectric layer 86 can be achieved through several processes, primarily dry etching, wet etching, or a combination of both, depending on material composition and selectivity requirements. Dry etching, such as reactive ion etching (RIE), can provide high precision and anisotropic profile control, ensuring that only the dielectric layer 86 is etched while leaving the underlying semiconductor layers and neighboring structures intact. Wet etching, using selective chemical etchants such as dilute hydrofluoric acid (HF) for silicon oxide (SiO₂) or phosphoric acid (H₃PO₄) for silicon nitride (SiN), can be applied without damaging the surrounding materials. Additionally, plasma ashing or vapor-phase etching using gases such as SF₆, CF₄, or NF₃ may be utilized to remove dielectric materials with high selectivity. In some embodiment, to selectively remove the dielectric layer 86 from only the n-type region 50N while preserving the dielectric layer 86 in the p-type region 50P, a mask can be employed by using photoresist patterning and lithography, where a protective photoresist layer is deposited and patterned over the p-type region 50P to shield it during the etching process. The unmasked n-type region 50N is then subjected to either a dry or wet etching process, removing the dielectric layer 86 while maintaining the integrity of the protected p-type region 50P. After the etching step is complete, the photoresist can be stripped using oxygen plasma ashing or a solvent-based removal process to fully expose the preserved dielectric layer 86 in the p-type region.

The epitaxial source/drain structures 92 in the n-type region 50N, e.g., the NMOS region, may be formed by masking the p-type region 50P, e.g., the PMOS region. Then, the epitaxial source/drain structures 92 are epitaxially grown in the first recesses 84 in the n-type region 50N. The epitaxial source/drain structures 92 may include any acceptable material appropriate for n-type nano-FETs. For example, if the second nanostructures 54 are silicon, the epitaxial source/drain structures 92 in the n-type region 50N may include materials exerting a tensile strain on the second nanostructures 54, such as Si, SiP, SiAs, SiP+SiAs/SiSb, SiSb, SiP+SiAs+SiSb, or the like.

The epitaxial source/drain structures 92 in the p-type region 50P, e.g., the PMOS region, may be formed by masking the n-type region 50N, e.g., the NMOS region. Then, the epitaxial source/drain structures 92 are epitaxially grown in the first recesses 84 in the p-type region 50P. The epitaxial source/drain structures 92 may include any acceptable material appropriate for p-type nano-FETs. For example, if the second nanostructures 54 are silicon, the epitaxial source/drain structures 92 in the p-type region 50P may include materials exerting a compressive strain on the second nanostructures 54, such as SiGe, Ge, GeSn, SiB, SiGe:B, SiGe:Ga, or the like.

The epitaxial source/drain structures 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain structures 92 may be in situ doped during growth.

As a result of the epitaxy processes used to form the epitaxial source/drain structures 92 in the n-type region 50N and the p-type region 50P, upper surfaces of the epitaxial source/drain structures 92 have facets which expand laterally outward beyond sidewalls of the nanostructures 55. In the embodiments illustrated in FIG. 10C, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI regions 68.

The epitaxial source/drain structures 92 may comprise one or more semiconductor material layers. For example, the epitaxial source/drain structures 92 may comprise a first semiconductor material layer 92A, a second semiconductor material layer 92B, and a third semiconductor material layer 92C. Any number of semiconductor material layers may be used for the epitaxial source/drain structures 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain structures 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B. In some embodiments, the epitaxial source/drain structure 92 can be doped with a dopant. The first semiconductor material layer 92A of the epitaxial source/drain structures 92 is adjacent the sidewall of the second nanostructure 54, and the second semiconductor material layer 92B of the epitaxial source/drain structures 92 is away from the sidewall of the second nanostructure 54. In some embodiments, a concentration of the dopant in the first semiconductor material layer 92A can be different from a concentration of the dopant in the second semiconductor material layer 92B. In some embodiments, a concentration of the dopant in the second semiconductor material layer 92B can be different from a concentration of the dopant in the third semiconductor material layer 92C.

A first interlayer dielectric (ILD) 96 is deposited over the epitaxial source/drain structures 92. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain structures 92, the masks 78, and the spacers 81 and 83. The CESL 94 may comprise a dielectric material, such as, silicon nitride, silicon oxide, silicon oxynitride, or the like, having a different etch rate than the material of the overlying first ILD 96.

A removal process is then applied to the first ILD 96 to remove excess first ILD 96 over the dummy gates 76 or the masks 78. In some embodiments, a planarization process such as a chemical mechanical polish (CMP), an etch-back process, combinations thereof, or the like may be utilized. The planarization process exposes the dummy gates 76 or the masks 78 such that top surfaces of the dummy gates 76 or the masks 78 and the first ILD 96 are level after the planarization process is complete.

The first ILD 96 is then recessed. The first ILD 96 is recessed such that upper portions of the epitaxial source/drain structures 92 protrude from the first ILD 96. Further, the top surfaces of the recessed first ILD 96 may have a flat surface as illustrated, a convex surface, a concave surface (such as dishing), or a combination thereof. The top surfaces of the first ILD 96 may be formed flat, convex, and/or concave by an appropriate etch. The first ILD 96 may be recessed using an acceptable etching process, such as one that is selective to the material of the insulation material (e.g., etches the material of the insulation material at a faster rate than the material of the CESL) 94). For example, an oxide removal using, for example, dilute hydrofluoric (dHF) acid may be used.

Subsequently, a second ILD 97 is deposited over the first ILD 96. The second ILD 97 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the second ILD 97 may be made of a different material than the first ILD 96.

After the second ILD 97 is deposited, a planarization process, such as a CMP, may be performed to level the top surface of the second ILD 97 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the second ILD 97 are level within process variations. Accordingly, the top surfaces of the dummy gates 76 are exposed through the second ILD 97. In some embodiments, the masks 78 may remain, in which case the planarization process levels the top surface of the first ILD 96 with top surface of the masks 78 and the gate spacers 81.

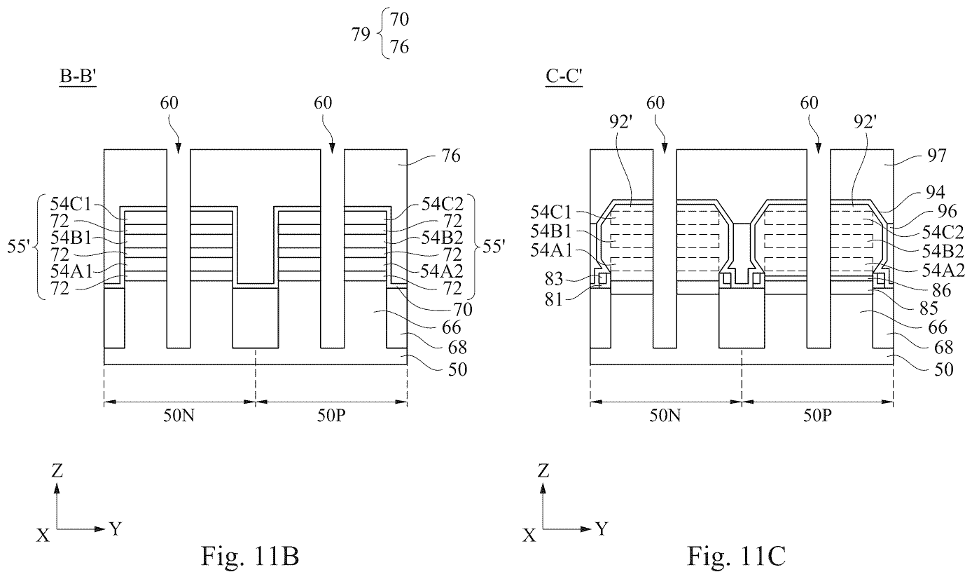

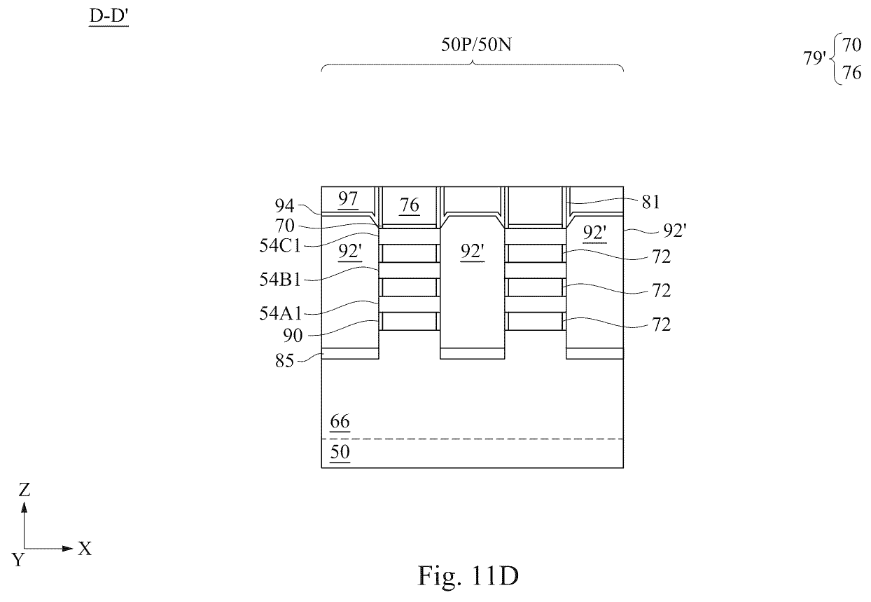

Reference is made to FIGS. 11A-11D. FIGS. 11A-11D illustrate cutting at least one of the fins 66 and nanostructures 55 into at least two sub-nanostructures 55′ and at least one of the epitaxial source/drain structures 92 into at least two sub-epitaxial source/drain structures 92′. In this embodiment, a nanostructure cut 60 is in a direction parallel or along the longitudinal axis of nanostructures 55 and fins 66. The second nanostructures 54A-C have been cut to form first nanostructures 52A1-C1, 52A2-C2 and second nanostructures 54A1-C1 and 54A2-C2. In the sub-nanostructures 55′, the nanostructure cut 60 forms two separate vertical stacks of second nanostructures 54A1-C1 and 54A2-C2.

In some embodiments, the dummy gate structure 79, which includes the dummy gate dielectric 70 and the mask 78, can also undergo a cutting process to form at least two sub-dummy gates 79′. During this process, the dummy gate dielectric 70 is divided into sub-dummy gate dielectrics 70′ and the dummy gate 76 is split into sub-dummy gates 76′, and the mask 78 is patterned to form sub-masks 78′. The resulting sub-dummy structures 79′ can remain aligned with the sub-channel regions and sub-source/drain features, maintaining proper gate control while ensuring compatibility with subsequent replacement gate formation, enabling the integration of multiple gate segments within a compact layout while preserving electrical isolation.

The nanostructure cut 60 may be formed using an extreme ultraviolet (EUV) lithography process with one or more mask layers (not shown) formed over the nanostructures 55, fins 66, and epitaxial source/drain structures 92. EUV lithography is an advanced semiconductor manufacturing technique that uses very short wavelength light (typically 13.5 nm) to pattern extremely small features. This process enables the creation of intricate structures at dimensions below 10 nm. EUV lithography emits EUV light that is focused to project the desired pattern onto a mask, such as a photoresist (not shown). In the context of creating the nanostructure cut 60 in the nanostructure 55, EUV lithography may provide the precision needed to accurately pattern the narrow gaps and fine features required.

After the EUV patterning of the photoresist, the nanostructures 55, fins 66, and epitaxial source/drain structures 92 may be patterned using an etching process to form the nanostructure cut 60 and forming two sub-epitaxial source/drain structures 92′ out of the single nanostructures 55 and two sub-nanostructures 55′ out of the single epitaxial source/drain structures 92. The nanostructure cut 60 may extend completely through the nanostructure 55 and at least partially into the fin 66. Additionally, the nanostructure cut 60 may extend completely through the epitaxial source/drain structures 92 and at least partially into the fin 66. In some embodiments, the nanostructure cut 60 in FIGS. 11A-11C can allow for the single nanostructure 55 and the single epitaxial source/drain structures 92 to be cut and be formed into at least two n-type nano-FET devices. In some embodiments, the nanostructure cut 60 can be parallel to the longitudinal axis of the nanostructure 55 and results in sub-nanostructures 55′ that have the same length as the prior nanostructure 55 and have a smaller width than the prior nanostructures 55. Additionally, the nanostructure cut 60 can be parallel to the longitudinal axis of the nanostructure 55 and results in sub-epitaxial source/drain structures 92′ that have the same length as the prior epitaxial source/drain structures 92 and have a smaller width than the prior epitaxial source/drain structures 92.

In some embodiments, the nanostructure 55 and the epitaxial source/drain structures 92 can be initially formed with larger dimensions before being patterned into smaller structures, specifically sub-nanostructures 55′ and sub-epitaxial source/drain structures 92′. This process can enable a reduction in the spacing between adjacent sub-nanostructures 55′, allowing for a more compact transistor layout that enhances device scaling and density. Similarly, the distance between adjacent sub-epitaxial source/drain structures 92′ can be also minimized, improving carrier transport efficiency and reducing resistance. By first creating larger structures and subsequently refining them through precise patterning, this method can ensure greater uniformity and precision in feature dimensions while maintaining high-performance electrical characteristics.

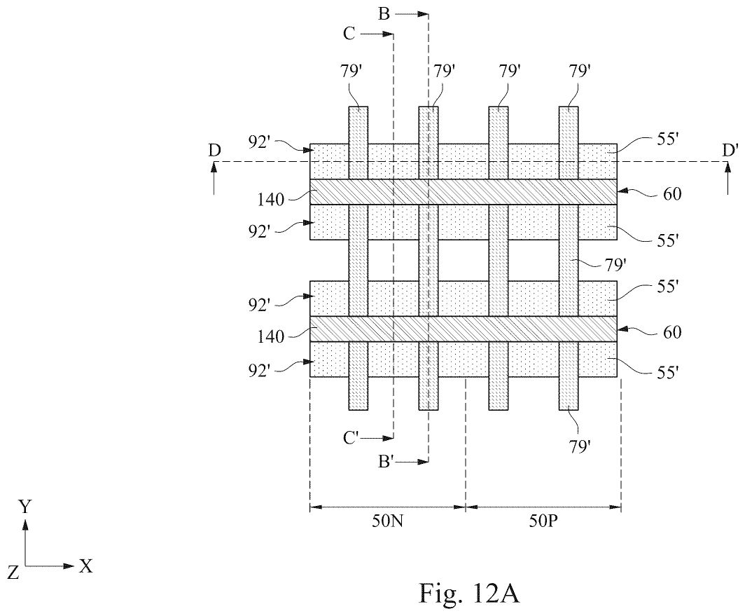

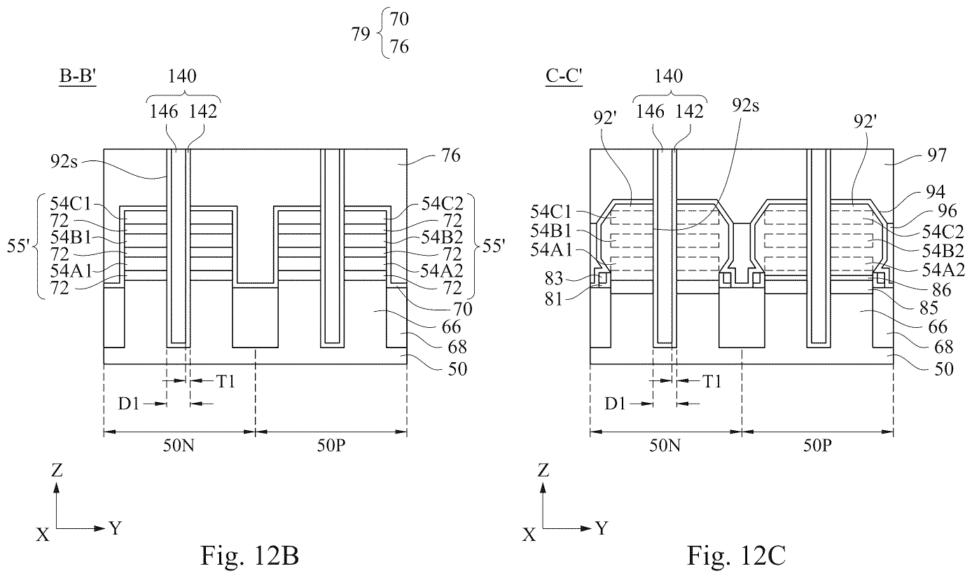

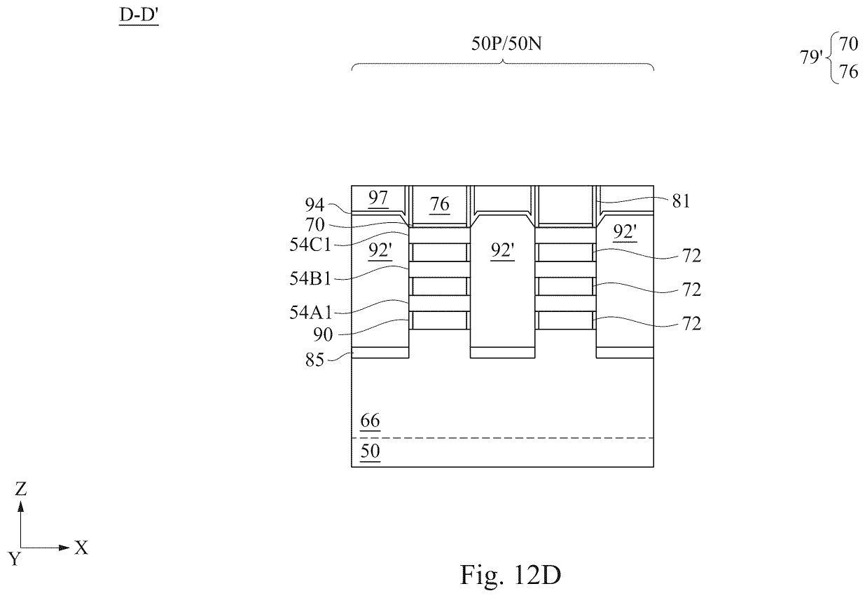

Reference is made to FIGS. 12A-12D. A dielectric layer 142 is deposited over the nanostructure cut 60. In some embodiments, the dielectric layer 142 may include silicon nitride or silicon nitride and may be deposited using CVD or ALD. As shown in FIGS. 12B and 12C, the deposited dielectric layer 142 may be conformally deposited over the nanostructure cut 60 to interface a sidewall of the fin 66 (see FIGS. 12B and 12C), a sidewall of the sub-nanostructure 55′ (see FIG. 12B), a sidewall of the dummy gate 76 (see FIG. 12B), a sidewall of the sub-epitaxial source/drain structure 92′ (see FIG. 12C), a sidewall of the semiconductive layer 85 (see FIG. 12C), a sidewall of the dielectric layer 86 (see FIG. 12C), a sidewall of the CESL 94 (see FIG. 12C), a sidewall of first ILD 96 (see FIG. 12C), and a sidewall of second ILD 97 (see FIG. 12C). In some embodiments, the dielectric layer 142 may have a thickness T1 of between about 1 and 5 nm, such as about 1, 2, 3, 4, or 5 nm. While not explicitly shown in the figures, the dielectric layer 142 may be a multilayer. In some embodiments, the dielectric layer 142 can be interchangeable referred to as a liner.

A dielectric layer 146 is deposited over the dielectric layer 142. In some embodiments, the dielectric layer 146 may include silicon oxide and may be deposited using flowable CVD (FCVD), spin-on coating, CVD, or ALD. The dielectric layer 146 not only completely fills the nanostructure cut 60 but also include a thickness over the top surfaces of the dummy gate 76 (see FIG. 12B) and the second ILD 97 (see FIG. 12C). In this example, the oxygen blocking layer 144 may include SiN, SiCN, SiOC, SiOCN, the like, or combinations thereof. In some embodiments, the dielectric layer 146 can be made of a different material than the dielectric layer 142.

Subsequently, a planarization process is performed to expose the dummy gate 76. The planarization process may include a chemical mechanical polishing (CMP) process. The planarization process is performed to remove excess of the dielectric layers 146 and to expose the top surface of the dummy gate 76. At this stage, an isolation feature 140 is substantially formed. In some embodiments, the isolation feature 140 can be interchangeable referred to as a wall structure, a dielectric material structure, a dielectric layer, or an isolation structure.

As the epitaxial source/drain structure 92 undergoes an etching process to create the nanostructure cut 60, it is subsequently divided into two sub-epitaxial source/drain structures 92′. This etching process can define the separation between the sub-epitaxial structures while ensuring that one side of each sub-epitaxial source/drain structure 92′ comes into direct contact with the isolation feature 140. The contact interface with the isolation feature 140 can results in the formation of a flat surface 92s (see FIG. 12C). In some embodiments, the surface 92s can be a vertical plane that aligns seamlessly with the sidewalls of the semiconductive layer 85, the dielectric layer 86, and the fin 66, contributing to a well-structured and uniform semiconductor architecture. As illustrated in FIG. 12C, the sub-epitaxial source/drain structure 92′ can exhibit an asymmetrical pattern along the Z-direction, which is a direct result of the etching process and the positioning of the isolation feature 140.

When multiple sub-epitaxial source/drain structures 92′ are formed using the isolation feature 140, the process can effectively prevent lateral epitaxial growth and variation, ensuring that adjacent sub-epitaxial source/drain structures 92′ remain distinctly separated without unintentional bridging, allowing for a reduction in the spacing between adjacent sub-epitaxial structures and achieving a separation distance D1 of less than about 30 nm. In some embodiments, the spacing can be further reduced to values such as about 10, 12, 14, 16, 18, 20, 22, 24, 26, or 28 nm. This approach enhances device integration density while maintaining electrical isolation and preventing unintended short circuits, thereby improving both performance and manufacturability in advanced semiconductor devices.

Reference is made to FIGS. 13A-13D. The dummy gates 76, and the masks 78 if present, are removed in one or more etching steps, so that second recesses 98 are formed and the portion of nanostructure cut 60 previously under the dummy gates 76 is exposed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of sub-nanostructures 55′, which act as channel regions in subsequently completed nano-FETs. Portions of the sub-nanostructures 55′ which act as the channel regions are disposed between neighboring pairs of the sub-epitaxial source/drain structures 92′. During the removal, the dummy gate dielectrics 70 may be used as etch stop layers when the dummy gates 76 are etched. The dummy gate dielectrics 70 may then be removed after the removal of the dummy gates 76. In some embodiments, the second recess 98 can be interchangeable referred to as a gate trench.

Subsequently, the sacrificial material 72 is removed, which extends the second recesses 98 to between the second nanostructures 54. In the sub-nanostructure 55′ with the longitudinal nanostructure cut 60, the second recesses 98 are extended to the nanostructure cut 60 forming two separate vertical stacks of second nanostructures 54A1-C1 and 54A2-C2. As illustrated in FIG. 14B, each of the second nanostructures 54A1-C1 and 54A2-C2 may have a height H1 and a length L1. The height H1 is measured in a direction perpendicular to a major surface of the substrate 50. The length L1 is measured in a direction parallel to a major surface of the substrate 50. In some embodiments, the ratio of L1 to H1 is greater than 1. If the ratio of the L1 to H1 is less than 1, the structure may have more defects.

The removal of the sacrificial material 72 may involve an isotropic etching process, such as a wet etching using dilute hydrofluoric acid (HF) or a chemical oxide removal (COR) dry etch. These etchants are selective to the materials of the sacrificial material 72, ensuring that the second nanostructures 54 remain relatively unetched in comparison to the sacrificial material 72. The sacrificial material 72 may be completely removed, or a residue of the sacrificial material 72 may remain on sidewalls of the inner spacers in the second recesses 98.

In some embodiments, the dielectric layer 142 can be removed simultaneously with the removal of dummy gates 76, dummy gate dielectrics 70, and/or sacrificial material 72. as the dielectric layer 142 is removed simultaneously with the removal of dummy gates 76, dummy gate dielectrics 70, and/or sacrificial material 72, a void, referred to as space S1, may be formed between the nanostructures 54 and the dielectric layer 146. However, in some embodiments, the dielectric layer 142 may not be completely removed, leaving residual material 142r between nanostructures 54 and dielectric layer 146. The presence of the space S1 can allow for subsequent material deposition, facilitating the integration of additional functional layers within the transistor structure.

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not shown) at a top surface to protect the underlying STI regions 68 from etching while patterning and removing the sacrificial material 72. In such embodiments, the hard mask may comprise, for example, a nitride.

Reference is made to FIGS. 14A-14D. An interfacial layer 101, a gate dielectric layer 100, and a gate electrode 102 can be formed for replacement gate structures 105. The interfacial layer 101 can be formed around the second nanostructures 54. In some embodiments, the interfacial layer 101 is silicon oxide formed on exposed surfaces of semiconductor materials in the second recesses 98 by using, for example, thermal oxidation, chemical oxidation, wet oxidation or the like. As a result, surface portions of the second nanostructures 54 exposed in the second recesses 98 can be oxidized into silicon oxide to form interfacial layer 101. In some embodiments, the gate structure 105 can interface the top surface of the STI region 68. In some embodiments, the gate structure 105 can be interchangeable referred to as a functional gate structure, an active gate structure, a gate layer, a gate pattern, a gate line, or a gate.

The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the second ILD 97, the CESL 94, the spacers 81 and 83, and the STI regions 68. As illustrated in FIG. 14B, the gate dielectric layers 100 are formed to surround each of the second nanostructures 54A1-C1 and 54A2-C2.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like. In some embodiments, the gate dielectric layers 100 can include dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the dielectric constant of the gate dielectric layers 100 can greater than the dielectric constant of the first spacer 81 and/or the second spacer 83.

The gate electrodes 102 are deposited over the gate dielectric layers 100, respectively, and fill the remaining portions of the second recesses 98. As illustrated in FIG. 18A, the gate electrodes 102 are formed to surround each of the second nanostructures 54A1-C1 and 54A2-C2. The gate electrodes 102 may include a metal-containing material such as titanium nitride, titanium aluminum, titanium oxide, tantalum nitride, tantalum carbide, cobalt, ruthenium, aluminum, ruthenium, tungsten, combinations thereof, or multi-layers thereof. For example, although single layer gate electrodes 102 are illustrated in FIGS. 14B and 14D, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

For an n-type GAA FET, the gate electrode 102 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate electrode 102 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate electrode 102 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the second ILD 97 and/or the isolation feature 140. The remaining portions of material of the gate electrodes 102 and the gate dielectric layers 100 thus form replacement gate structures 105 of the resulting nano-FETs. The gate electrodes 102 and the gate dielectric layers 100 may be collectively referred to as “gate structures.”

In some embodiments, after the planarization process, the isolation feature 140 serves as a physical boundary that separates adjacent gate structures 105, ensuring that each gate remains electrically and structurally distinct. This isolation can prevent interference between neighboring transistors, maintaining optimal device functionality and reducing parasitic interactions. Additionally, the isolation feature 140 can act as an etch stop layer during the planarization process, providing a well-defined reference surface that prevents over-etching and ensures uniformity across the device structure. By defining the height and boundaries of the gate structures 105, the isolation feature 140 can contribute to enhanced patterning accuracy and manufacturing consistency, and therefore the isolation feature 140 can be interchangeably referred to as a self-aligned cut structure, as it enables precise alignment and patterning without the need for additional lithographic steps. This self-aligned approach can improve process scalability, reduces variability, and enhances the overall reliability of advanced semiconductor devices.

As shown in FIGS. 14E and 14F, in some embodiments, the gate structures 105 in different device regions (e.g., n-type region 50N and p-type region 50P) can be engineered with work function tuning layers of different materials or varying layer counts to optimize device performance. For example, the gate structure 105 in the p-type region 50P may have a greater number of work function tuning layers compared to the gate structure 105 in the n-type region 50N to achieve the desired threshold voltage (Vt) characteristics. To facilitate this selective patterning process, the isolation feature 140 can serve as a reference alignment structure for defining and modifying the work function metal layers 102a, which are simultaneously deposited across the substrate 50. This approach can ensure that the work function metal layers 102a in the n-type region 50N can be selectively removed, while the work function metal layers 102a in the p-type region 50P are retained, allowing for proper work function differentiation between nMOS and pMOS transistors.

For instance, a bottom anti-reflective coating (BARC) layer 103 (see FIG. 14E) can be deposited over the work function metal layers 102a in the p-type region 50P, using the isolation feature 140 as a reference. This selective BARC deposition can effectively protect the underlying metal layers in the p-type region while exposing the work function metal layers 102a in the n-type region 50N. Subsequently, an etching process can be performed to remove the exposed work function metal layers 102a in the n-type region 50N, leaving only the work function tuning layers in the p-type region 50P intact. This method can provides a precise and efficient approach to work function tuning layer differentiation, ensuring optimal threshold voltage control for both nMOS and pMOS transistors while maintaining high device density and alignment accuracy. By utilizing the isolation feature 140 as a reference, this process can enable fine patterning without requiring increased spacing between nanostructures 55, allowing for compact transistor layouts.

As shown in FIG. 14E, when using isolation feature 140 to pattern gate electrodes 102, the spacing between adjacent nanostructures 55 can be minimized to less than about 30 nm, with possible values including about 10, 12, 14, 16, 18, 20, 22, 24, 26, or 28 nm. Furthermore, this approach can ensure that the work function metal layers 102a remain intact during the patterning process, preventing damage or material loss that could compromise device performance. The isolation feature 140 can enable precise etching, maintaining the integrity of the work function metal layers 102a while ensuring that they form vertical sidewalls 102s, resulting in well-defined gate structures with minimal variability, improving electrical characteristics such as threshold voltage control, drive current, and subthreshold slope.

As shown in FIG. 14F, after the BARC layer 103 is removed, the fabrication process can continue by sequentially depositing the work function tuning layer 102b and a fill material 102c over both the n-type region 50N and the p-type region 50P, thereby completing the gate electrode 102. The work function tuning layers 102a and 102b can be selected to match the electrical characteristics required for each transistor type, optimizing charge carrier modulation in both n-type and p-type transistors. In some embodiments, the fill material 102c can include of metals such as tungsten (W), titanium nitride (TiN), or aluminum (Al). In other embodiments, the number of work function tuning layers, as well as the differences in the number of layers between the n-type region 50N and the p-type region 50P, may vary.

As shown in FIG. 14G, the gate dielectric layer 100 can be deposited within space S1, ensuring optimal coverage around the nanostructures 54 for enhanced gate control and improved electrostatic properties. By way of example and not limitation, within space S1 along the Y-direction, the gate dielectric layer 100 can have a dimension D2 ranging from approximately 1 to 5 nm, with possible values including 1, 1.5, 2, 2.5, 3, 3.5, 4, 4.5, or 5 nm, depending on process requirements. Along the Z-direction, the gate dielectric layer 100 can have a dimension D3 in the range of approximately 0.5 to 3 nm, with possible values such as 0.5, 1, 1.5, 2, 2.5, or 3 nm, providing precise control over the thickness of the dielectric material in relation to the surrounding transistor structures.

Additionally, the isolation feature 140, which provides critical structural and electrical separation, extends along the Y-direction with a dimension D4 that can range from approximately 10 to 30 nm, with possible values including 10, 12, 14, 16, 18, 20, 22, 24, 26, 28, or 30 nm. In the Z-direction, the top surface of the isolation feature 140 is positioned at a distance D5 (see FIGS. 12B and 12C) from the uppermost second nanostructure 54C, with a range of approximately 5 to 20 nm, including values such as 5, 10, 15, or 20 nm.

These precise dimensions contribute to the stability and performance of the transistor structure by ensuring controlled spacing between key semiconductor elements while maintaining an optimal gate dielectric profile for efficient electrostatic control. The careful formation and removal of dielectric layer 142, combined with the controlled integration of gate dielectric layer 100 within space S1, enable improved transistor characteristics, including reduced leakage, enhanced gate capacitance, and better overall scalability in advanced semiconductor nodes.

In some embodiments, a cut metal gate (CMG) structure 139 (see FIG. 14A) can be incorporated into the semiconductor device to enhance isolation, improve gate patterning precision, and optimize electrical performance. The CMG structure 139 can be positioned at the boundary of the device cell, serving as a structural and electrical partition between adjacent gate structures 105, ensuring that replacement gates remain well-defined, electrically independent, and properly isolated, reducing interference and minimizing gate-to-gate leakage. When viewed from above, as illustrated in FIG. 14A, the trench O1 can extend longitudinally along the nanostructures 55, creating a distinct separation between the replacement gates. The CMG process can include a selective etching step, which removes specific portions of the replacement gates, effectively separating them while preserving the surrounding device elements. This selective etching can result in the formation of a trench O1, as shown in FIG. 14A, which is a well-defined cut extending into the gate material. Following the formation of the trench O1, the next step can include filling this trench O1 with a dielectric material, which forms the CMG structure 139. The dielectric fill can ensure that the cut gates remain electrically isolated, preventing any unintended short circuits or capacitive coupling between adjacent gate electrodes. This dielectric-filled CMG structure 139 can serve as a robust insulating barrier, allowing for gate control, improved transistor performance, and enhanced device reliability.

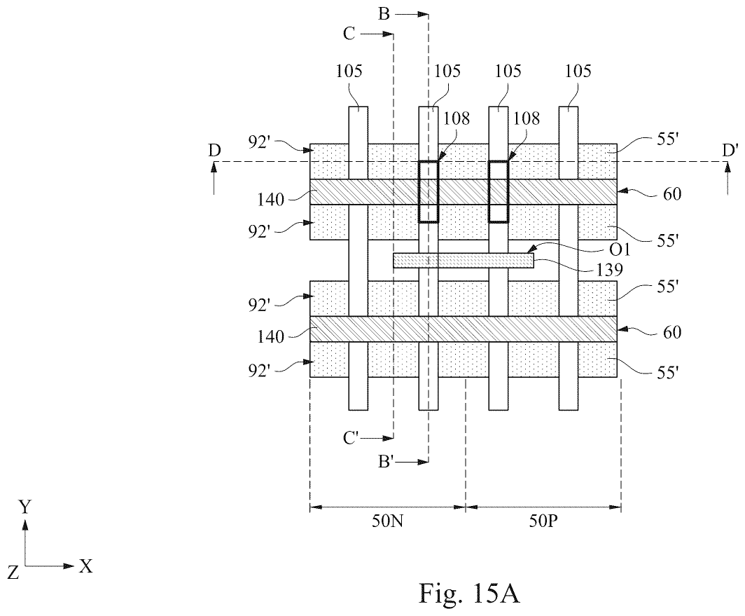

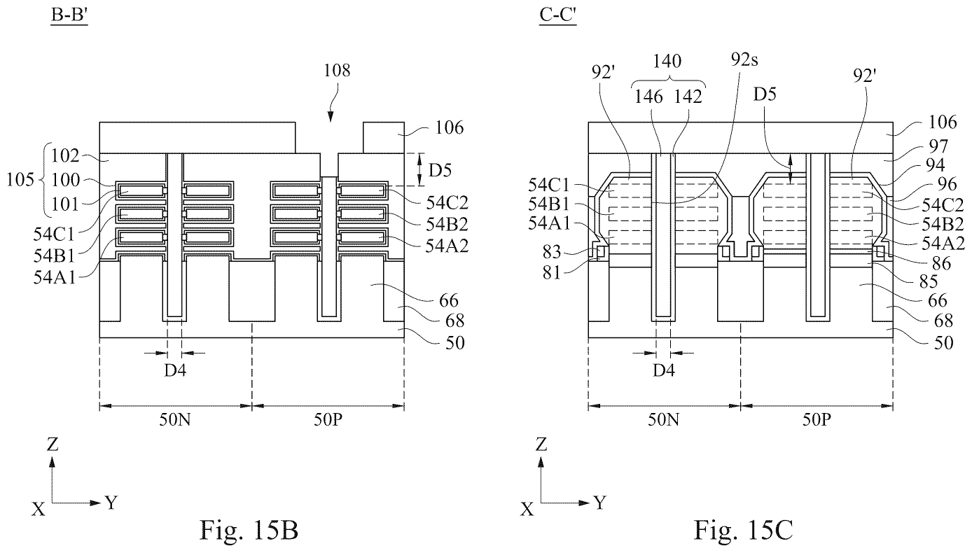

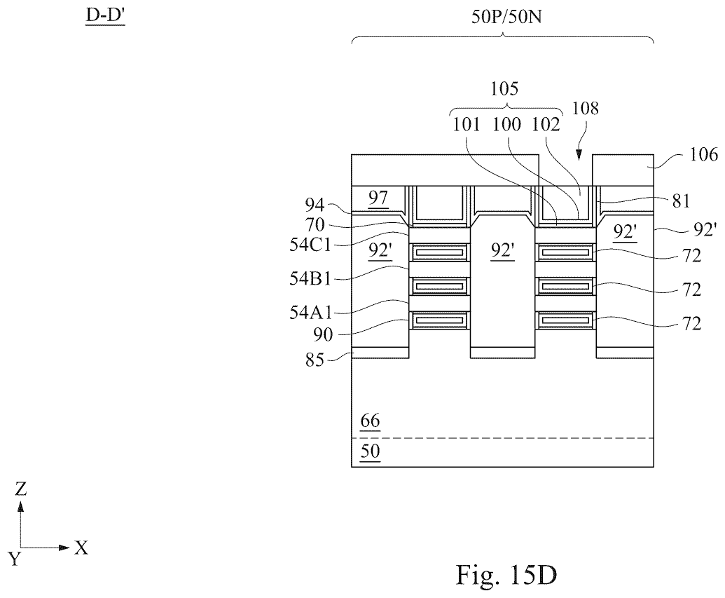

Reference is made to FIGS. 15A-15D. An ILD 106 is deposited over the second ILD 97. In some embodiments, the ILD 106 can be a flowable film formed by FCVD. In some embodiments, the ILD 106 is formed of a dielectric material such as PSG, BSG, BPSG, USG, or the like, and may be deposited by any suitable method, such as CVD, PECVD, or the like.

The ILD 106 can be etched to form recesses 108 exposing surfaces of the gate structure 105. The recesses 108 may be formed by etching using an anisotropic etching process, such as RIE, NBE, or the like. A mask, such as a photoresist, may be formed and patterned over the ILD 106 to mask portions of the ILD 106 from the etching process. In some embodiments, the etching process may over-etch, and therefore, the recesses 108 extend into the gate structure 105, and a bottom of the recesses 108 may be level with (e.g., at a same level, or having a same distance from the substrate), or lower than (e.g., closer to the substrate) the gate structure 105.

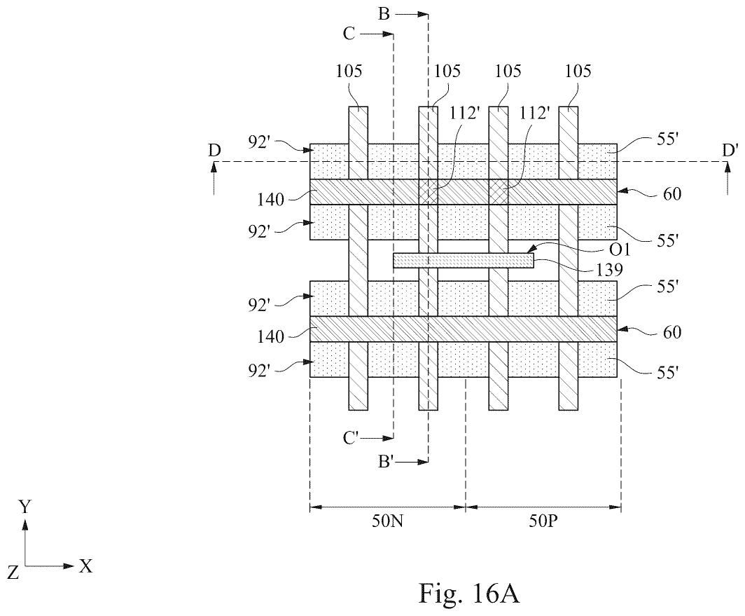

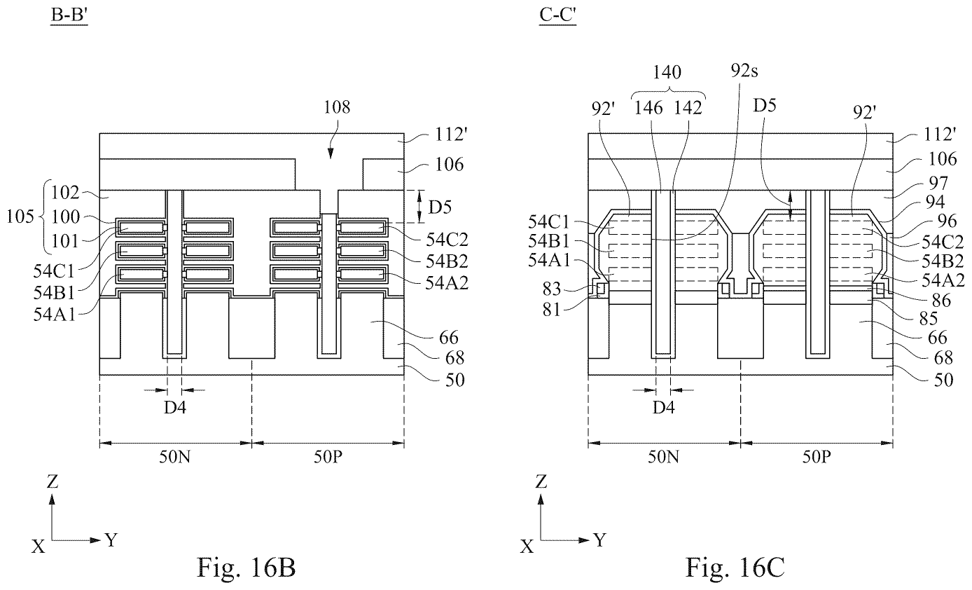

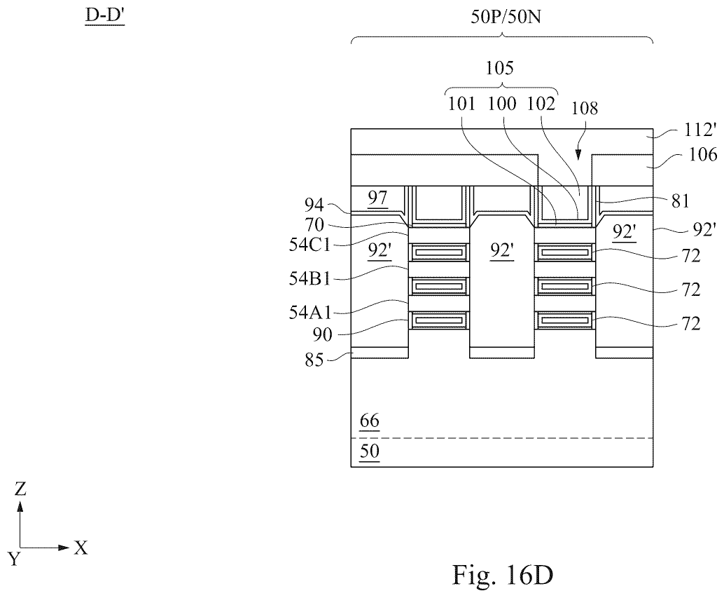

In some embodiments, the isolation feature 140 can undergoes downward etching, causing recess 108 to extend further downward. As a result, the portion of isolation feature 140 that is exposed within recess 108 can be etched to a lower height compared to the portion that remains covered by the ILD 106, ensuring that the isolation feature 140 maintains its insulating properties while allowing for structural modifications that facilitate improved contact formation. Following the etching of the isolation feature 140, the contact 112 (see FIG. 16B) can be subsequently formed within the recess 108. The increased depth of the recess 108 can allow the contact 112 to extend deeper, thereby increasing its contact area with the gate structure 105. This larger contact interface can improve electrical connectivity and reduce contact resistance.

In some embodiments, the process of downward etching of isolation feature 140 can be achieved using anisotropic dry etching techniques, such as reactive ion etching (RIE), which provides depth control and prevents unwanted lateral etching. Selective etching chemistries, such as fluorine-based etchants for silicon oxide (SiO₂) or silicon nitride (SiN), may be used to ensure high etch selectivity between the isolation feature 140 and surrounding materials. Additionally, plasma-based etching can be utilized to finely tune the etch rate, ensuring that the height reduction of isolation feature 140 within recess 108 aligns with design specifications.

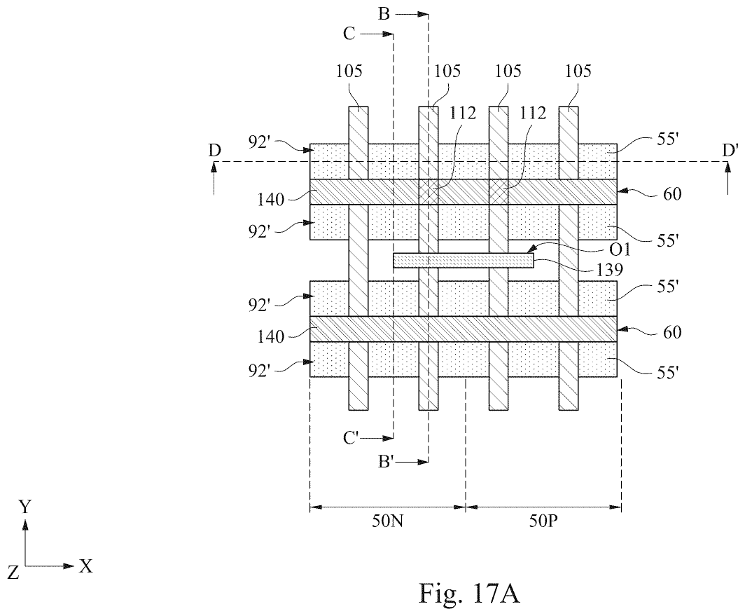

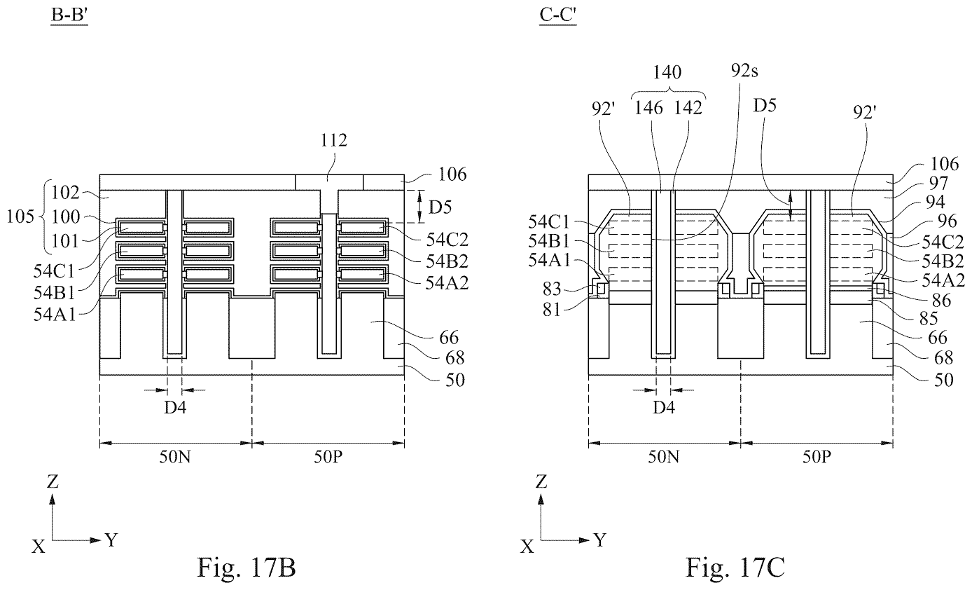

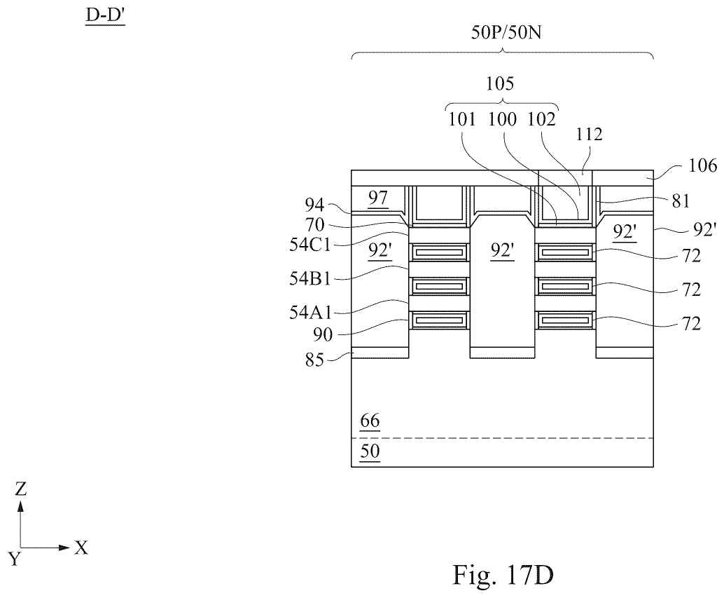

Reference is made to FIGS. 16A-17D. A contact 112 (may also be referred to as contact plugs) are formed in the recess 108. The contact 112 may each comprise one or more layers, such as barrier layers, diffusion layers, and fill materials. For example, in some embodiments, a filling layer 112′ including a barrier layer and a conductive material 112′ can be deposited over the substrate 50 an into the recess 108, and the filling layer 112′ can be electrically coupled to the underlying conductive feature (e.g., gate electrode 102 in the illustrated embodiment). The barrier layer may include titanium, titanium nitride, tantalum, tantalum nitride, or the like. The conductive material may be copper, a copper alloy, silver, gold, ruthenium, tungsten, cobalt, aluminum, nickel, or the like. In FIGS. 18A-18D, a planarization process, such as a CMP, may be performed to remove excess material from a surface of the ILD 106 to form the contacts 112 (see FIG. 17B). The contacts 112 are electrically coupled to the gate electrode 102 and may be referred to as gate contacts.

As shown in FIG. 17B, the contact 112 can exhibit a T-shaped profile, which is designed to optimize electrical connectivity and reduce resistance in advanced semiconductor devices. The T-shaped can ensure that the contact extends laterally over the gate region while maintaining a vertical connection to the underlying gate structures 105, which in turn increases the contact area, thereby reducing contact resistance and improving current conduction efficiency. The expanded upper portion of the T-shaped contact 112 can provide enhanced metal coverage, ensuring a more reliable and uniform electrical connection. Additionally, the pi-gate structure can improve short-channel effect (SCE) control. By extending the gate's influence over the channel region, the pi-gate structure can enhance electrostatic control, reducing leakage currents and improving transistor performance.

Reference is made to FIGS. 18A-18E. The ILD 106, the second ILD 97, and the CESL 94 are etched to form recesses 109 exposing surfaces of the sub-epitaxial source/drain structures 92′. The recesses 109 may be formed by etching using an anisotropic etching process, such as RIE, NBE, or the like. In some embodiments, the recesses 108 may be etched through the ILD 106 and the second ILD 97 using an etching process; and may then be etched through the CESL 94 using a second etching process. A mask, such as a photoresist, may be formed and patterned over the ILD 106 to mask portions of the ILD 106 from the first etching process. In some embodiments, the etching process may over-etch, and therefore, the recesses 109 extend into the sub-epitaxial source/drain structures 92′. The recesses 109, and a bottom of the recesses 108 may be level with (e.g., at a same level, or having a same distance from the substrate), or lower than (e.g., closer to the substrate) the sub-epitaxial source/drain structures 92′. Although FIG. 18E illustrate the recesses 108 and 109 as exposing the sub-epitaxial source/drain structures 92′ and the gate structure 105 in a same cross section, in various embodiments, the sub-epitaxial source/drain structures 92′ and the gate structure 105 may be exposed in different cross-sections, thereby reducing the risk of shorting subsequently formed contacts.

After the recesses 109 are formed, silicide regions 110 are formed over the sub-epitaxial source/drain structures 92′. In some embodiments, the silicide regions 110 are formed by first depositing a metal (not shown) capable of reacting with the semiconductor materials of the underlying sub-epitaxial source/drain structures 92′ (e.g., silicon, silicon germanium, germanium) to form silicide or germanide regions, such as nickel, cobalt, titanium, tantalum, platinum, ruthenium, tungsten, other noble metals, other refractory metals, rare earth metals or their alloys, over the exposed portions of the sub-epitaxial source/drain structures 92′, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, a contact 114 (may also be referred to as contact plugs) are formed in the recesses 109. The contact 114 may each comprise one or more layers, such as barrier layers, diffusion layers, and fill materials. For example, in some embodiments, the contact 114 each can include a barrier layer and a conductive material, and is electrically coupled to the underlying conductive feature (e.g., silicide region 110 in the illustrated embodiment). The contact 114 can be electrically coupled to the silicide regions 110 and may be referred to as source/drain contact. The barrier layer may include titanium, titanium nitride, tantalum, tantalum nitride, or the like. The conductive material may be copper, a copper alloy, silver, gold, ruthenium, tungsten, cobalt, aluminum, nickel, or the like. A planarization process, such as a CMP, may be performed to remove excess material from a surface of the ILD 106. In some embodiments, an electrical conductivity of the contact 114 can be greater than an electrical conductivity of the source/drain structures 92 (or sub-epitaxial source/drain structure 92′). In some embodiments, an electrical conductivity of the silicide region 110 can be between the electrical conductivity of the source/drain structures 92 (or sub-epitaxial source/drain structure 92′) and the electrical conductivity of the contact 114.

In some embodiments, as shown in FIG. 18D, a helmet structure 115 can be formed over the isolation feature 140 before the formation of the contact 114, serving as an electrical isolation layer that prevents adjacent sub-epitaxial source/drain structures 92′ from shorting through the contact 114. The helmet structure 115 can be positioned to provide a dielectric barrier, ensuring that each contact remains electrically independent. In some embodiments, the helmet structure 115 can have a dimension D6 along the Z-direction, which can range from about 1 to 19 nm, with possible values including about 1, 2, 3, 4, 5, 6, 7, 8, 9, 10, 11, 12, 13, 14, 15, 16, 17, 18, or 19 nm, ensuring that the helmet structure 115 effectively isolates the contacts 114 while maintaining compatibility with the surrounding device architecture. In some embodiments, the helmet structure 115 can include of metal oxides such as hafnium oxide (HfO₂), zirconium oxide (ZrO₂), or other high-k dielectric materials. In some embodiments, the helmet structure 115 can be interchangeable referred to as a dielectric material structure, a dielectric layer, or an isolation structure.

During fabrication, the helmet structure 115 can be first deposited onto the isolation feature 140 and embedded within the ILD 106 to define the location where contact 114 will be formed. This pre-defined structure can ensure precision in subsequent patterning steps. The ILD 106 is then selectively etched, leveraging material selectivity to remove only the ILD 106 while leaving the helmet structure 115 intact, thereby creating openings O2 that expose the underlying sub-epitaxial source/drain structures 92′. These openings O2 can be symmetrically positioned on opposite sides of the helmet structure 115. Following this etching process, contact material can be deposited within the openings O2, ensuring direct electrical coupling with the exposed sub-epitaxial source/drain structures 92′. A planarization process, such as chemical mechanical polishing (CMP), is then performed to remove excess material from the surface of the ILD 106, refining the final contact structure and ensuring a uniform surface profile, resulting in the well-defined contact 114. In some embodiments, the helmet structure 115 can be interchangeably referred to as a self-aligned cut structure, facilitating self-aligned contact formation and ensuring tight design rules without requiring additional lithographic steps.

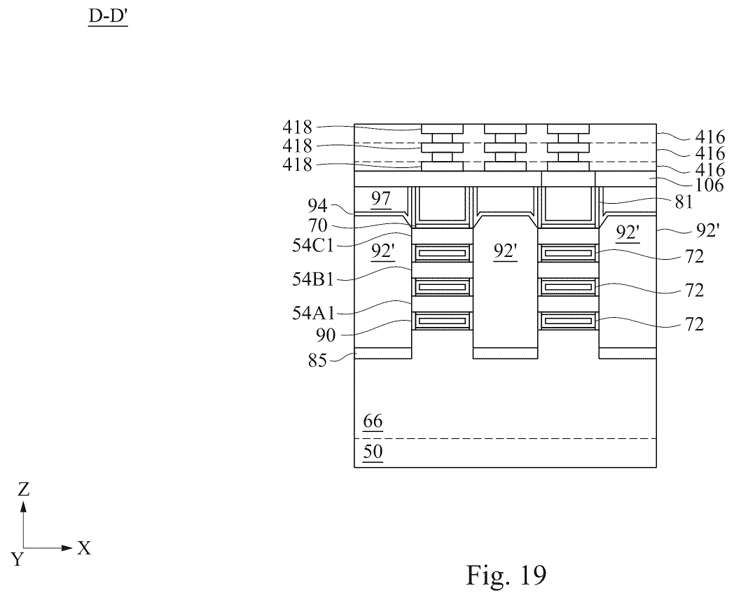

Reference is made to FIG. 19. A front-side interconnect structure 414 can be formed. The front-side interconnect structure 414 includes dielectric layers 416 and layers of conductive features 418 in the dielectric layers 416. The dielectric layers 416 may include low-k dielectric layers formed of low-k dielectric materials. The dielectric layers 416 may further include passivation layers, which are formed of non-low-k and dense dielectric materials such as undoped silicate-glass (USG), silicon oxide, silicon nitride, or the like, or combinations thereof over the low-k dielectric materials. The dielectric layers 416 may also include polymer layers.

The conductive features 418 may include conductive lines and vias, which may be formed using damascene processes. Conductive features 418 may include metal lines and metal vias, which includes diffusion barriers and a copper containing material over the diffusion barriers. There may also be aluminum pads over and electrically connected to the metal lines and vias. In some embodiments, a dielectric constant of the gate dielectric layer 100 can be greater than a dielectric constant of at least one of the dielectric layers 416 in the interconnect structure 414.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments introduces a method for cell height scaling in transistors, enabling active region space reduction while overcoming fabrication challenges. The method introduces a wall-fill process, preventing epitaxial bridging, gate misalignment, and work function metal (WFM) damage, which in turn optimizes MPG and cut-metal gate CMG windows, enhances lateral epitaxial growth control, and improves isolation through dielectric wall, and therefore ensuring higher device density and improving process scalability and transistor performance.

In some embodiments, a method includes forming a first channel region and a second channel region over a substrate; an isolation feature disposed over the substrate and between the first channel region and the second channel region; forming a gate structure over the first channel region and the second channel region; forming a first source/drain feature interfacing a sidewall of the first channel region, wherein the first source/drain feature is doped with a dopant, wherein the first source/drain feature comprises a first layer adjacent the sidewall of the first channel region and a second layer away from the sidewall of the first channel region, and a concentration of the dopant in the first layer is different from a concentration of the dopant in the second layer; forming a second source/drain feature interfacing a sidewall of the second channel region; forming an etch stop layer continuously extending from over the first source/drain feature to over the second source/drain feature; forming an interlayer dielectric (ILD) layer over the etch stop layer, wherein a top surface of the isolation feature is spaced apart from the ILD layer by the etch stop layer; patterning the first channel region to form a first sub-channel region and a second sub-channel region, wherein the gate structure overlying the first channel region is concurrently patterned to form a first sub-gate structure over the first sub-channel region and a second sub-gate structure over the second sub-channel region.

In some embodiments, the method further includes patterning the first source/drain feature to form a first sub-source/drain feature adjacent to the first sub-gate structure and a second sub-source/drain feature adjacent to the second sub-gate structure, wherein the first and second sub-source/drain features are physically separated. In some embodiments, patterning the first channel region, patterning the gate structure, and patterning the first source/drain feature are performed simultaneously. In some embodiments, patterning the first channel region and patterning the gate structure comprise: etching the first channel region and the gate structure to form a recess extending between the first sub-channel region and the second sub-channel region and extending between the first sub-channel region and the second sub-gate structure. In some embodiments, the method further includes depositing a dielectric material within the recess to physically isolate the second sub-channel region from the first sub-channel region and physically isolate the second sub-gate structure from the first sub-gate structure; planarizing the dielectric material, such that a top surface of the dielectric material is substantially level with a top surface of the gate structure. In some embodiments, the dielectric material has a height relative to the first sub-channel region ranging from about 5 to 20 nm. In some embodiments, the method further includes forming a metal contact over the dielectric material. In some embodiments, the method further includes forming a dielectric liner along a sidewall of the recess before depositing the dielectric material; removing the first sub-gate structure and the second sub-gate structure after planarizing the dielectric material; after removing the first and second sub-gate structures, selectively removing at least a portion of the dielectric liner to expose the dielectric material; forming a first gate over the first sub-channel region and a second gate over the second sub-channel region. In some embodiments, the dielectric material comprises SiN, SiCN, SiOC, SiOCN, or combinations thereof. In some embodiments, a spacing distance between the first sub-channel region and the second sub-channel region is less than about 25 nm.

In some embodiments, a method includes forming a channel region over a substrate; forming an isolation feature disposed over the substrate and adjacent to a sidewall of the channel region; forming a gate structure over the channel region and interfacing a top surface of the isolation feature; forming a source/drain feature interfacing a sidewall of the channel region; forming an interlayer dielectric (ILD) layer disposed over the source/drain feature; etching the source/drain feature to form a first sub-source/drain feature and a second sub-source/drain feature, wherein the first and second sub-source/drain features are physically separated by a recess; depositing a dielectric material within the recess to physically isolate the second sub-source/drain feature from the first sub-source/drain feature; forming a source/drain contact extending through the ILD layer to electrically couple to the first sub-source/drain feature, wherein an electrical conductivity of the source/drain contact is greater than an electrical conductivity of the source/drain feature.

In some embodiments, the method further includes etching the channel region to form a first sub-channel region and a second sub-channel region, wherein the first and second sub-channel regions are physically separated by the recess; etching the gate structure to form a first sub-gate structure and a second sub-gate structure, wherein the first and second sub-gate structures are physically separated by the recess. In some embodiments, a spacing distance between the first sub-source/drain feature and the second sub-source/drain feature is less than about 25 nm. In some embodiments, in a cross-sectional view along a lengthwise direction of the gate structure, the first sub-source/drain feature has a vertically asymmetric pattern. In some embodiments, the method further includes forming an dielectric structure within the recess to physically isolate the second sub-source/drain feature from the first sub-source/drain feature; forming an isolation structure over the dielectric structure. In some embodiments, the isolation structure is made of metal oxide.

In some embodiments, a semiconductor structure includes a first transistor, a second transistor, a dielectric structure, a metal silicide layer, a first dielectric layer, a contact feature, and an interconnect structure. The first transistor includes a first gate structure interfacing at least three surfaces of a first channel and a first epitaxial source/drain feature interfacing a sidewall of the first channel, wherein the first gate structure comprises a first gate dielectric layer over the first channel and a first gate electrode over the first gate dielectric layer. The second transistor includes a second gate structure interfacing at least three surfaces of a second channel and a second epitaxial source/drain feature interfacing a sidewall of the second channel, wherein the second gate structure comprises a second gate dielectric layer over the second channel and a second gate electrode over the second gate dielectric layer. The dielectric structure is disposed between the first and second gate structures, extends between the first and second channels, and further extends between the first and second epitaxial source/drain features, wherein, in a top view, the dielectric structure extends lengthwise in a direction different from to a longitudinal axis of the first gate structure. The metal silicide layer is over the first epitaxial source/drain feature. The first dielectric layer is disposed over the first and second epitaxial source/drain features. The contact feature extends through the first dielectric layer and is over the metal silicide layer, wherein the contact feature is surrounded by the first dielectric layer, and an electrical conductivity of the metal silicide layer is between an electrical conductivity of the first epitaxial source/drain feature and an electrical conductivity of the contact feature. The interconnect structure disposed over the contact feature, wherein the interconnect structure comprises interconnect layers, wherein each of the interconnect layers comprises metal lines disposed in a second dielectric layer, wherein a first one of the metal lines in a first one of the interconnect layers is spaced apart from a second one of the metal lines in a second one of the interconnect layers by one of the second dielectric layer, wherein the first one of the metal lines is electrically coupled to the second one of the metal lines by a via disposed in the one of second dielectric layer.

In some embodiments, in a cross-sectional view along the longitudinal axis of the first gate structure, the dielectric structure has a lateral dimension ranging from about 10 to 30 nm. In some embodiments, the dielectric structure is in contact with the first gate dielectric layer of the first transistor and the second gate dielectric layer of the second transistor. In some embodiments, the semiconductor structure further includes a dielectric remainder interposing between the first channel of the first transistor and the dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first channel region and a second channel region over a substrate;
forming an isolation feature disposed over the substrate and between the first channel region and the second channel region;
forming a gate structure over the first channel region and the second channel region;
forming a first source/drain feature interfacing a sidewall of the first channel region, wherein the first source/drain feature is doped with a dopant, wherein the first source/drain feature comprises a first layer adjacent the sidewall of the first channel region and a second layer away from the sidewall of the first channel region, and a concentration of the dopant in the first layer is different from a concentration of the dopant in the second layer;
forming a second source/drain feature interfacing a sidewall of the second channel region;
forming an etch stop layer continuously extending from over the first source/drain feature to over the second source/drain feature;
forming an interlayer dielectric (ILD) layer over the etch stop layer, wherein a top surface of the isolation feature is spaced apart from the ILD layer by the etch stop layer; and
patterning the first channel region to form a first sub-channel region and a second sub-channel region, wherein the gate structure overlying the first channel region is concurrently patterned to form a first sub-gate structure over the first sub-channel region and a second sub-gate structure over the second sub-channel region.

2. The method of claim 1, further comprising:
patterning the first source/drain feature to form a first sub-source/drain feature adjacent to the first sub-gate structure and a second sub-source/drain feature adjacent to the second sub-gate structure, wherein the first and second sub-source/drain features are physically separated.

3. The method of claim 2, wherein patterning the first channel region, patterning the gate structure, and patterning the first source/drain feature are performed simultaneously.

4. The method of claim 1, wherein patterning the first channel region and patterning the gate structure comprise:
etching the first channel region and the gate structure to form a recess extending between the first sub-channel region and the second sub-channel region and extending between the first sub-channel region and the second sub-gate structure.

5. The method of claim 4, further comprising:
depositing a dielectric material within the recess to physically isolate the second sub-channel region from the first sub-channel region and physically isolate the second sub-gate structure from the first sub-gate structure; and
planarizing the dielectric material, such that a top surface of the dielectric material is substantially level with a top surface of the gate structure.

6. The method of claim 5, wherein the dielectric material has a height relative to the first sub-channel region ranging from about 5 to 20 nm.

7. The method of claim 5, further comprising:
forming a metal contact over the dielectric material.

8. The method of claim 5, further comprising:
forming a dielectric liner along a sidewall of the recess before depositing the dielectric material;
removing the first sub-gate structure and the second sub-gate structure after planarizing the dielectric material;
after removing the first and second sub-gate structures, selectively removing at least a portion of the dielectric liner to expose the dielectric material; and
forming a first gate over the first sub-channel region and a second gate over the second sub-channel region.

9. The method of claim 5, wherein the dielectric material comprises SiN, SiCN, SiOC, SiOCN, or combinations thereof.

10. The method of claim 1, wherein a spacing distance between the first sub-channel region and the second sub-channel region is less than about 25 nm.

11. A method, comprising:
forming a channel region over a substrate;
forming an isolation feature disposed over the substrate and adjacent to a sidewall of the channel region;
forming a gate structure over the channel region and interfacing a top surface of the isolation feature;
forming a source/drain feature interfacing a sidewall of the channel region;
forming an interlayer dielectric (ILD) layer disposed over the source/drain feature;
etching the source/drain feature to form a first sub-source/drain feature and a second sub-source/drain feature, wherein the first and second sub-source/drain features are physically separated by a recess;
depositing a dielectric material within the recess to physically isolate the second sub-source/drain feature from the first sub-source/drain feature; and
forming a source/drain contact extending through the ILD layer to electrically couple to the first sub-source/drain feature, wherein an electrical conductivity of the source/drain contact is greater than an electrical conductivity of the source/drain feature.

12. The method of claim 11, further comprising:
etching the channel region to form a first sub-channel region and a second sub-channel region, wherein the first and second sub-channel regions are physically separated by the recess; and
etching the gate structure to form a first sub-gate structure and a second sub-gate structure, wherein the first and second sub-gate structures are physically separated by the recess.

13. The method of claim 11, wherein a spacing distance between the first sub-source/drain feature and the second sub-source/drain feature is less than about 25 nm.

14. The method of claim 11, wherein, in a cross-sectional view along a lengthwise direction of the gate structure, the first sub-source/drain feature has a vertically asymmetric pattern.

15. The method of claim 11, further comprising:
forming an dielectric structure within the recess to physically isolate the second sub-source/drain feature from the first sub-source/drain feature; and
forming an isolation structure over the dielectric structure.

16. The method of claim 15, wherein the isolation structure is made of metal oxide.

17. A semiconductor structure, comprising:
a first transistor comprising a first gate structure interfacing at least three surfaces of a first channel and a first epitaxial source/drain feature interfacing a sidewall of the first channel, wherein the first gate structure comprises a first gate dielectric layer over the first channel and a first gate electrode over the first gate dielectric layer;
a second transistor comprising a second gate structure interfacing at least three surfaces of a second channel and a second epitaxial source/drain feature interfacing a sidewall of the second channel, wherein the second gate structure comprises a second gate dielectric layer over the second channel and a second gate electrode over the second gate dielectric layer;
a dielectric structure disposed between the first and second gate structures, extending between the first and second channels, and further extending between the first and second epitaxial source/drain features, wherein, in a top view, the dielectric structure extends lengthwise in a direction different from a longitudinal axis of the first gate structure;
a metal silicide layer over the first epitaxial source/drain feature;
a first dielectric layer disposed over the first and second epitaxial source/drain features;
a contact feature extending through the first dielectric layer and over the metal silicide layer, wherein the contact feature is surrounded by the first dielectric layer, and an electrical conductivity of the metal silicide layer is between an electrical conductivity of the first epitaxial source/drain feature and an electrical conductivity of the contact feature; and
an interconnect structure disposed over the contact feature, wherein the interconnect structure comprises interconnect layers, wherein each of the interconnect layers comprises metal lines disposed in a second dielectric layer, wherein a first one of the metal lines in a first one of the interconnect layers is spaced apart from a second one of the metal lines in a second one of the interconnect layers by one of the second dielectric layer, wherein the first one of the metal lines is electrically coupled to the second one of the metal lines by a via disposed in the one of second dielectric layer.

18. The semiconductor structure of claim 17, wherein in a cross-sectional view along the longitudinal axis of the first gate structure, the dielectric structure has a lateral dimension ranging from about 10 to 30 nm.

19. The semiconductor structure of claim 17, wherein the dielectric structure is in contact with the first gate dielectric layer of the first transistor and the second gate dielectric layer of the second transistor.

20. The semiconductor structure of claim 17, further comprising:
a dielectric remainder interposing between the first channel of the first transistor and the dielectric structure.
